(19) United States
(12) Patent Application Publication
(10) Pub. No.: US 2021/0399204 A1
(43) Pub. Date: Dec. 23, 2021

(54) IMPROVEMENTS IN OR RELATING TO ENERGY GENERATION IN A PIEZOELECTRIC SWITCH

(71) Applicant: University of Hertfordshire Higher Education Corporation, Hatfield Hertfordshire (GB)

(72) Inventors: Mohammad Reza Herfatmanesh, Hatfield Hertfordshire (GB); Nathan Counsell, Hatfield Hertfordshire (GB)

(21) Appl. No.: 17/292,126

(22) PCT Filed: Nov. 8, 2019
(86) PCT No.: PCT/GB2019/053173

§ 371 Date: May 7, 2021

(30) Foreign Application Priority Data
Nov. 9, 2018 (GB) 1818294.9

(51) Int. Cl. H01L 41/113; H01L 41/053; H02N 2/18

(52) U.S. Cl. CPC H01L 41/1134; H02N 2/181; H02N 2/186; H01L 41/053

(57) ABSTRACT

The present invention provides an energy harvesting system that removes the need for batteries for sensing and actuating purposes through the use of energy harvesting materials such as piezoelectric transducers. The present invention particularly provides clamping and actuation mechanisms for energy harvesting applications including energy harvesting switches, more particularly energy harvesting wireless switches. The present invention is designed to produce sufficient instantaneous energy to power low-power circuits such as radio transmitters, allowing for seamless integration with existing smart devices. In addition, the system benefits from battery less operation, eliminating the need for regular battery maintenance and replacement as well as end of life recycling. An energy harvesting system is provided comprising:
a) an energy harvesting material which generates energy when deformed or moved from a first position to a second position; and
b) an energy generator support which has first and second mounting supports between which the energy harvesting material is mounted in the first position wherein the first and second mounting supports each have an internal surface and the internal surfaces are each provided with a layer of a resilient material and a layer of a non-resilient material wherein the layer of the non-resilient material engages the energy harvesting material.

### FIELD OF THE INVENTION

The present invention provides an energy harvesting system that removes the need for batteries for sensing and actuating purposes through the use of energy harvesting materials such as piezoelectric transducers. The present invention particularly provides clamping and actuation mechanisms for energy harvesting applications including energy harvesting switches, more particularly energy harvesting wireless switches. The present invention is designed to produce sufficient instantaneous energy to power low-power circuits such as radio transmitters, allowing for seamless integration with existing smart devices. In addition, the system benefits from battery-less operation, eliminating the need for regular battery maintenance and replacement as well as end of life recycling.

### BACKGROUND OF THE INVENTION

Smart home electronics is a rapidly growing sector, where both sensors and actuators are becoming a more intrinsic part of everyday life. However, the existing technologies have inherent limitations some of which are listed here. Mains powered products require existing infrastructure, for example, built in wiring which limits the location of devices. In contrast, battery powered products are more versatile as they can be mobile. However, a major drawback is the fact that some batteries are made from rare earth materials, which are often toxic. Consequently, disposal of batteries is of concern since most batteries end up in landfills where toxic chemicals leak to the environment causing damage to the ecosystem and wildlife. Advancement in battery technology is comparatively slow to reach commercial application, this has left devices being oversized or underpowered. Although rechargeable batteries reduce the number of times a battery is replaced, this type of battery is limited by the number of charge—discharge cycles, typically between 100-4000. Energy harvesting researchers have investigated the use of piezoelectric materials as a method of generating energy to power ultra-low-power systems. However, only a few have successfully transmitted a signal and found that very little data can be transmitted due to the inherently low amount of energy produced by their actuation methods. Most have used a piezoelectric ignitor type system where single crystal quartz is struck with a hammer to generate extremely high voltages. Use of this material is limited by its piezoelectric properties where very little power is produced.

### SUMMARY OF THE INVENTION

According to a first aspect of the present invention there is provided an energy harvesting system comprising:
a) an energy harvesting material which generates energy when deformed or moved from a first position to a second position; and
b) an energy generator support which has first and second mounting supports between which the energy harvesting material is mounted in the first position wherein the first and second mounting supports each have an internal surface and the internal surfaces are each provided with a layer of a resilient material and a layer of a non-resilient material wherein the layer of the non-resilient material engages the energy harvesting material.

The mounting supports in one alternative may be mounting brackets.

Preferably the non-resilient material provides a barrier between the energy harvesting material and the resilient material.

The layer of non-resilient material serves three purposes; protects the resilient material from being cut by the energy harvesting material's substrate, allows for easy assembly of the full device, and houses energy harvesting material securely (reducing unwanted movement). Without the layer of non-resilient material, the substrate of the energy harvesting material could cut the resilient material, causing premature failure of the device where the resilient material is formed from a soft material such as a hyperelastic material such as silicone. The layer of non-resilient material eliminates these negative aspects to the system, significantly increasing the lifetime of the device.

Preferably the layer of non-resilient material is a protective sleeve.

Preferably the resilient material comprises a hyperelastic material such as silicone, alternatively the resilient material comprises a spring, such as a leaf spring or a laminated spring. In a preferred embodiment the resilient material comprises silicone due to its excellent longevity and commercial availability.

Preferably the energy harvesting material comprises an electroactive polymer, an electret and/or a piezoelectric material.

Examples of electroactive polymers include a dielectric electroactive polymer such as a dielectric elastomer, a ferroelectric polymer such as PVDF, an electrostrictive graft polymer and/or a liquid crystalline polymer such as a natural or synthetic piezoelectric material. Examples of electrets include a ferroelectret, a real-charge electret and/or an oriented-dipole electret; for example, an electret formed from a synthetic polymer such as a fluoropolymer, polypropylene and/or polyethyleneterephthalate. Examples of ferroelectrets include one or more layers of a cellular polymer or polymer foam formed from a polymer such as polycarbonate, perfluorinated or partially fluorinated polymers such as PTFE, fluoroethylenepropylene (FEP), perfluoroalkoxyethylenes (PFA), polypropylene, polyesters, polyethylene terephthalate (PET), polyethylene naphthalate (PEN), cycloolefin polymers, cyclo-olefin copolymers, polyimides, polymethyl methacrylate (PMMA) and/or polymer blends.

Examples of suitable piezoelectric materials include a natural material (for example silk) or a synthetic material (such as a polymeric and/or ceramic material). A suitable piezoelectric polymer includes a semi-crystalline polymer or an amorphous dipolar polymer. Suitable semi-crystalline piezoelectric polymers include polyvinylidene fluoride (PVDF), a PVDF copolymer (such as polyvinylidene fluoride tetrafluoroethylene (PVDF-TrFE)) or terpolymer (such as polyvinylidene fluoride tetrafluoroethylene chlorotrifluoroethylene (PVDF-TrFE-CTFE)), polyamides, liquid crystal polymers and/or poly(p-xylylene) (such as Parylene-C). Suitable amorphous dipolar piezoelectric polymers include polyimide and/or polyvinylidene chloride.

A suitable ceramic piezoelectric material includes a particle of lead titanate such as lead zirconate titanate (PZT) or PMT-PT, lead potassium niobate, sodium potassium niobate (NKN), bismuth ferrite, sodium niobate, bismuth titanate, sodium bismuth titanate, barium titanate, potassium niobate, lithium niobate, lithium tantalite, sodium tungstate, zinc oxide and/or barium sodium niobate. In some embodiments, the ceramic material may be in the form of a particle. In some embodiments, the piezoelectric layer may comprise one or more polymer layers wherein one or more of the polymer layers comprise a particle of piezoelectric ceramic material.

Preferably energy harvesting material comprises a planar piezoelectric element.

Planar piezoelectric elements are the most common form of energy harvester, the limitation of such products is the low power output due to minimal inflicted stress within the structure upon actuation. Extensive research has been performed on this type of harvester finding that cantilevers should be implemented to achieve higher deflection which results in higher stress being generated within the piezoelectric element. These systems are controlled by the natural frequency of the cantilever which is often very high due to the product being small. Furthermore, these systems need vibrational input to achieve higher output energies. To reduce the natural frequency of the system proof masses can be added, however, a significant mass often has to be used to reduce the natural frequency to mechanical input frequencies below 1 Hz which makes the setup bulkier. This pre-loaded system allows for input to be as infrequent or frequent as the end user requires, whilst maintaining an output energy high enough to power low-power devices. Such configuration is ideal for real life applications where frequencies are often less than 1 Hz.

Previous research work has demonstrated that due to the deformation of the piezoelectric transducers under pre-load a bi-stable can be generated. This allows for the transducer to snap between two stable states. This is undesirable since extra mechanisms would be required for the system to return to the original position which reduces the output energy of the system. To overcome this shortcoming, a compressible wall has been developed to allow the transducer to snap through and return back to the original position upon single actuation. However, to achieve a long lasting and reliable system where the piezoelectric transducers do no fracture due to excessive stress a compressible condition is required. When mechanical force is applied to the pre-loaded piezoelectric transducer a horizontal force is exerted on the internal walls of the mounting supports and if the internal walls are incompressible extra force will be transferred to the ceramic surface of the piezo causing damage beyond repair. To avoid this, a compressible wall has been implemented which absorbs some of the actuation energy allowing the transducers to buckle. However, when the force is removed from the piezoelectric transducer the stored energy in the system causes the piezoelectric transducer to snap back to its original position.

Preferably the piezoelectric element comprises a piezoelectric transducer.

Preferably the piezoelectric element comprises a piezoelectric ceramic PZT.

Preferably the piezoelectric element comprises a single layer piezoelectric square, circle or rectangle.

Preferably the piezoelectric element comprises a plurality of piezoelectric elements. Preferably the piezoelectric element comprises two piezoelectric elements. More preferably the piezoelectric element comprises three piezoelectric elements.

Preferably where a plurality of piezoelectric elements are provided the system further comprises a clamp configured to clamp the elements together such that they act as a single element.

In one alternative the clamp comprises a band of cellulose, such as cellulose tape, which is adhered to the top and bottom piezoelectric elements, by for example an adhesive material. The band of cellulose is advantageous as it is both an insulator and is flexible. In another alternative the clamp comprises an injection moulded plastics band. The clamping of a plurality of piezoelectric elements together using such clamp allows for the piezoelectric elements to be actuated in phase with the behaviour of a single piezoelectric element.

When multiple piezoelectric transducers are used clamping should be implemented, this makes the transducers act as a single unit enhancing the output energy. Without clamping transducers may get stuck in the inverted position, reducing the output energy of the system. In addition, the stuck piezoelectric would absorb the electric energy from the other transducers on subsequent actuations. The clamping system ensures that a smooth signal is produced, maximising the amount of energy produced by the system.

Preferably the piezoelectric element is rectangular or square.

Preferably the energy harvesting material is a flexible energy harvesting material comprising a flexible upper electrode, a layer of piezoelectric material and a resilient lower electrode wherein the layer of piezoelectric material is arranged between the upper and lower electrodes. The electrodes allow the electrical charge generated to be captured and used to power electrical circuits or in the alternative be stored. Preferably the electrode comprises conductive tape which is adhered to the surface of the piezoelectric material. This is advantageous as the use of conductive tape removes the need to solder onto the surface of the piezoelectric material. Soldering is an issue, as heat above 130° C. will result in the loss of piezoelectric properties due to the Curie point being met. Furthermore, the use of a conductive tape reduces the overall size of the product and ensures that forces are transmitted uniformly to the piezoelectric material. Preferably the conductive tape comprises conductive copper tape. The use of copper reduces the resistance, thus, reducing the losses of the system.

Preferably deformation or movement of the energy harvesting material from the first position to the second comprises physical actuation, in one alternative this is a push, in another alternative this is a pull. In a further alternative the deformation or movement of the energy harvesting material comprises indirect actuation, in one alternative this is achieved through hydraulic actuation which allows for the device to be more compact, in another alternative this is achieved through the application of a magnetic force, this method reduces the mechanical wear in the overall system, thus increasing the lifetime of the device.

In one alternative the energy generator support comprises two portions which are connected together. The two portions of the energy generator support can be connected together in multiple ways; screw, nuts and bolts, split pin, pop rivet or welded joints.

In one alternative the two portions of the energy generator support are connected together with a living hinge. The two portions of the energy generators support may be integrally formed with the living hinge. The two portions of the energy generators support may be integrally formed with the living hinge by means of moulding, such as injection moulding, or 3 d printing from a plastics material. In one alternative the two portions of the energy generator support cooperate to form a clamp to retain the energy harvesting material in position within the energy generator support.

In another alternative the energy generator support comprises a single portion. When formed as a single portion the energy generator support may be formed from extrusion, moulding or 3D printing.

The energy harvesting system can be manufactured from multiple materials including; plastics and metals and also from natural materials such as wood, bamboo or even stone. The use of metals allows for the device size to be reduced even further whilst maintaining the same structural strength as plastics at the expense of cost and weight. The device can be produced through several methods, 3D printing for plastic and CNC for metal prototypes. For high volumes the use of injection moulding for plastics or casting for metals should be considered.

5

This novel system which incorporates an energy harvesting material such as a piezoelectric ceramic PZT removes the need for mains power or batteries to power a low-power smart sensor. The structure of the harvester amplifies the energy output of the energy harvesting material significantly through increasing the stress induced within the structure upon actuation, allowing the device to power low-power smart systems instantaneously by a single actuation without the need for a battery storage. Thus, this is a long-life system that needs no extra maintenance saving time and money for the end user.

According to a second aspect of the present invention there is provided a switch comprising an energy harvesting system as described in the first aspect of the invention. The switch could be for example a single button, which could be on the microscale, and could be scaled or arranged in an array for use in flooring applications for example. In a further alternative a plurality of the energy harvesting systems may be stacked with the aid of actuation points which would mean that a greater force could be used to cause the actuation resulting in the buckling of the energy harvesting material so that it could be used on roads, which would allow for actuation by vehicles for example which would generate significantly higher amounts of energy.

### BRIEF DESCRIPTION OF THE DRAWINGS

Other aspects and features of the present invention will become apparent to those ordinarily skilled in the art upon review of the following description of specific embodiments of the invention in conjunction with the accompanying figures.

FIG. 1 illustrates a top plan view of a first embodiment of an energy harvesting system according to the present invention;

FIG. 2 illustrates a perspective view of the first embodiment of the energy harvesting system according to the present invention;

FIG. 3 illustrates an exploded perspective view of the first embodiment of the harvesting system according to the present invention;

FIG. 4 illustrates a top plan view of a second embodiment of an energy harvesting system according to the present invention;

FIG. 5 illustrates a top plan view of a third embodiment of an energy harvesting system according to the present invention;

FIG. 6 illustrates a top plan view of a fourth embodiment of an energy harvesting system according to the present invention;

FIG. 7 illustrates a side view of the fourth embodiment of the energy harvesting system according to the present invention;

FIG. 8 illustrates a perspective view of multiple piezoelectric transducers in a clamped arrangement;

FIG. 9 illustrates a side view of multiple piezoelectric transducers in a clamped arrangement;

FIG. 10 illustrates a perspective view of an alternative sleeve;

FIG. 11 illustrates a perspective view of an alternative sleeve;

FIG. 12 illustrates a perspective view of an alternative sleeve;

FIG. 13 illustrates a perspective view of an energy harvesting array having two energy harvesting systems;

FIG. 14 illustrates a perspective view of multiple piezoelectric transducers in a clamped arrangement with electrodes;

FIG. 15 illustrates a side view of multiple piezoelectric transducers in a clamped arrangement with electrodes;

FIG. 16 illustrates a perspective view of a fifth embodiment of the energy harvesting system according to the present invention;

FIG. 17 illustrates a side view of the fifth embodiment of the energy harvesting system according to the present invention;

FIG. 18 illustrates an exploded perspective view of the fifth embodiment of the energy harvesting system according to the present invention;

FIG. 19 illustrates a top open perspective view of a sixth embodiment of the energy harvesting system according to the present invention;

FIG. 20 illustrates a bottom open perspective of the sixth embodiment of the energy harvesting system according to the present invention;

FIG. 21 illustrates a bottom open exploded perspective view of the sixth embodiment of the energy harvesting system according to the present invention;

FIG. 22 illustrates a top closed perspective of the sixth embodiment of the energy harvesting system according to the present invention;

FIG. 23 illustrates a bottom closed perspective view of the sixth embodiment of the energy harvesting system according to the present invention;

FIG. 24 illustrates an open perspective of a seventh embodiment of the energy harvesting system according to the present invention; and

FIG. 25 illustrates a closed perspective view of the seventh embodiment of the energy harvesting system according to the present invention.

### DETAILED DESCRIPTION OF PREFERRED EMBODIMENTS

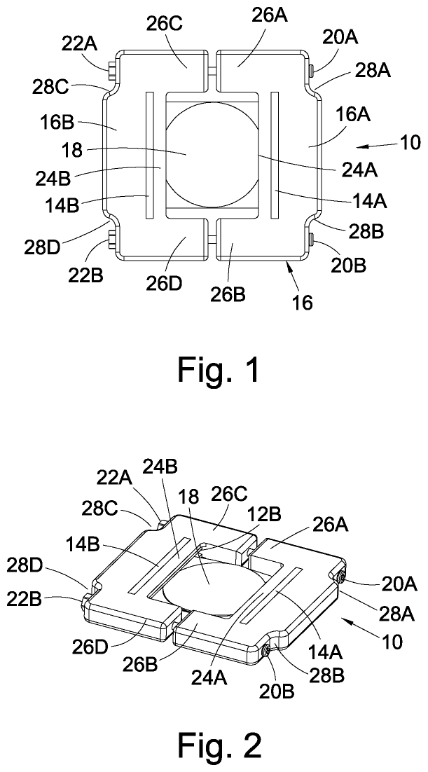

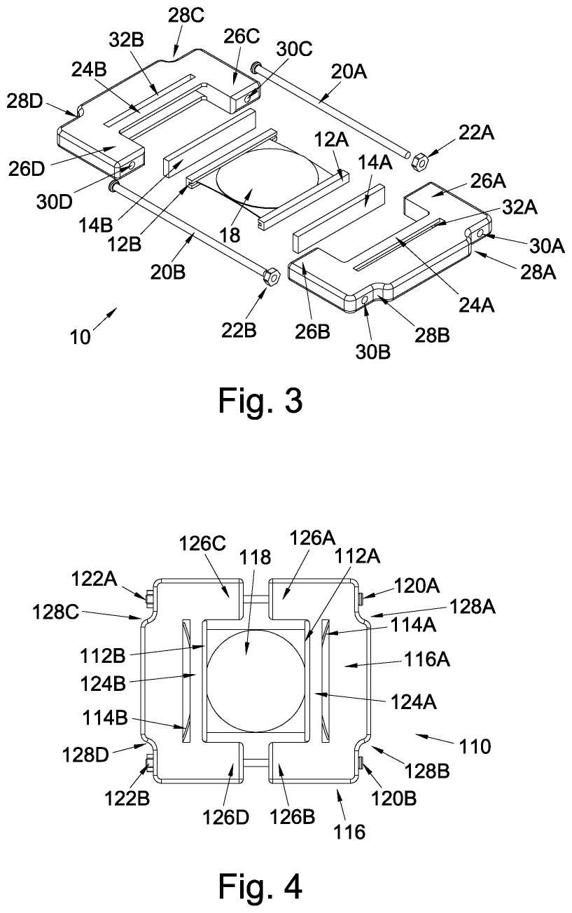

FIGS. 1 to 3 illustrate a first embodiment of an energy harvesting system 10 according to the present invention. The harvesting system 10 has an energy generator support 16 which is formed in two parts 16A, 16B which are connected together through the use of clamping bolts 20A, 20B which pass through corresponding apertures 30A, 30B, 30C, 30D provided in the two parts 16A, 16B of the energy generator support 16. The clamping bolts 20A, 20B are secured in place using nuts 22A, 22B, in the embodiment illustrated the nuts 22A, 22B are M1.8 nuts and the clamping bolts 20A, 20B are M1.8 bolts of 40 mm length. The size of the clamping bolts and nuts which are suitable for use will depend on the size of the energy generator support. In the alternative to a nut and bolt arrangement the two parts 16A, 16B of the energy generator support 16 may instead be connected together by screws, split pins, pop rivets or welding. In the case of pop rivets or welding the connection would be permanent.

The two parts 16A, 16B of the energy generator support 16, provide mounting supports between which energy harvesting material 18 is mounted. In the embodiment illustrated the energy harvesting material 18 is a piezoelectric transducer, in the embodiment illustrated there is a single piezoelectric transducer, in the alternative there may be a plurality of piezoelectric transducers stacked on top of one another.

Where a plurality of piezoelectric transducers are provided which are stacked on top of one another in order for the piezoelectric transducers to operate as a single energy harvesting material they need to be clamped together as illustrated in FIGS. 8 and 9. FIGS. 8 and 9 illustrate the use of 3 piezoelectric transducers 418A, 418B, 418C to form energy harvesting material 418. A clamping band 440 is provided to clamp the piezoelectric transducers 418A, 418B, 418C together to ensure that the electrical signal output from each of the piezoelectric transducers 418A, 418B, 418C is in phase and to improve the consistency and reliability. In the embodiment illustrated the clamping band 440 is an adhesive tape which is wound or wrapped around the piezoelectric transducers 418A, 418B, 418C. In an alternative the clamping band 440 is an adhesive cellulose tape, in a further alternative the clamping band 440 is formed from an injection moulded plastics material.

FIGS. 14 and 15 illustrate the use of 3 piezoelectric transducers 818A, 818B, 818C to form energy harvesting material 818. A clamping band 840 is provided to clamp the piezoelectric transducers 818A, 818B, 818C together to ensure that the electrical signal output from each of the piezoelectric transducers 818A, 818B, 818C is in phase and to improve the consistency and reliability. In the embodiment illustrated the clamping band 840 is an adhesive tape which is wound or wrapped around the piezoelectric transducers 818A, 818B, 818C. In an alternative the clamping band 840 is an adhesive cellulose tape, in a further alternative the clamping band 840 is formed from an injection moulded plastics material. A flexible upper electrode 850A, 850B, 850C and a resilient lower electrode 852A, 852B, 852C are provided for each of the piezoelectric transducers 818A, 818B, 818C wherein each of the piezoelectric transducers 818A, 818B, 818C is arranged between the upper 850A, 850B, 850C and lower electrodes 852A, 852B, 852C. The electrodes 850A, 850B, 850C, 852A, 852B, 852C allow the electrical charge generated to be captured and used to power electrical circuits or in the alternative be stored. In the embodiment illustrated the electrodes 850A, 850B, 850C, 852A, 852B, 852C comprise conductive copper tape which is adhered to the respective upper or lower surface of the piezoelectric material. Each flexible upper electrode 850A, 850B, 850C is provided with a layer of protective insulating material 854A, 854B, 854C, and each resilient lower electrode 852A, 852B, 852C is provided with a layer of protective insulating material 856A, 856B, 856C. The protective insulting material 854A, 854B, 854C, 856A, 856B, 856C ensures that there is no short between the electrodes 850A, 850B, 850C, 852A, 852B, 852C. The layer of protective insulating material 854A, 854B, 854C, 856A, 856B, 856C can simply be a plastic tape.

The two parts 16A, 16B of the energy generator support 16 which act as the mounting supports each have an internal surface 32A, 32B which is provided with a layer of resilient material 14A, 14B. In the embodiment illustrated the layer of resilient material 14A, 14B, is silicone rubber, in the alternative another hyperelastic material may be used, in another alternative the resilient material could be a spring, such as a leaf spring or a laminated spring. The layer of resilient material 14A, 14B is used to reduce the buckling force and allow the energy harvesting material 18, in this case a piezoelectric transducer, to return to its original position.

The two parts 16A, 16B of the energy generator support 16 which act as the mounting supports each have a sleeve clamp 24A, 24B and are provided with a sleeve 12A, 12B. The sleeve 12A, 12B is formed from a non-resilient material such as a metallic material such as aluminium or steel or a plastics material such as polylactic acid (PLA) or acrylonitrile butadiene styrene (ABS), preferably where a metallic material is used the metallic material is provided with a coating of a non-conducting material such as a powder coating which also reduces the risk of corrosion of the sleeves 12A, 12B. The sleeve 12A, 12B is mounted onto the layer of resilient material 14A, 14B. The sleeve 12A, 12B is then retained in position by sleeve clamp 24A, 24B which extends along both sides of the length of the sleeve 12A, 12B. In the embodiment illustrated the sleeve clamp 24A, 24B is formed integrally in each of the two parts 16A, 16B of the energy generator support 16. The sleeve 12A, 12B, is retained in position by sleeve clamp 24A, 24B such that it is able to move backwards and forwards in the same plane as the resilient material 14A, 14B, and the energy harvesting material 18, as energy harvesting material 18 and the resilient material 14A, 14B is deformed, but is not able to move in any other direction.

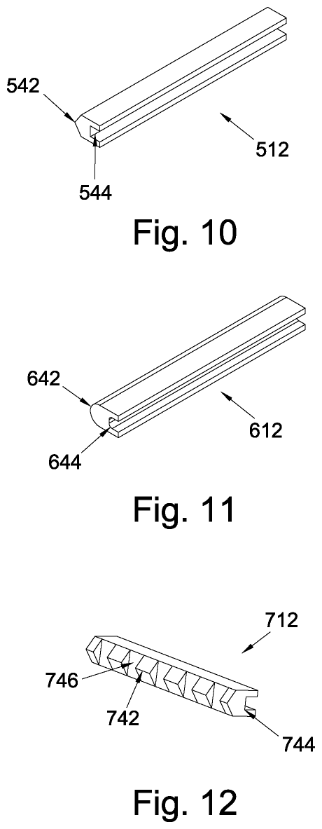

In the embodiment illustrated sleeves 12A, 12B are generally a square C-shape. However, in the alternative the sleeve 12A, 12B may be other shapes as illustrated in FIGS. 10 to 12. Whilst these sleeves 512, 612, 712 are also generally C-shaped they have additional features.

Referring to FIG. 10 sleeve 512 is illustrated which is provided with a triangular edge 542 which increases the pressure exerted onto the resilient material. This increased pressure alters the spring stiffness of the resilient material, particularly where the resilient material is a hyperelastic material which results in higher buckling loads of the energy harvesting material with smaller geometric arcs, i.e. smaller deformations, which increases the power output of the energy harvesting material. The use of a staggered wall contact in the form of the triangular edge 542 achieves a higher spring constant. Sleeve 512 is also provided with a square C-shaped slot 544 for ease of locating the energy harvesting material.

Referring to FIG. 11 sleeve 612 is illustrated which is provided with a curved edge 642 which increases the pressure exerted onto the resilient material. This increased pressure alters the spring stiffness of the resilient material, particularly where the resilient material is a hyperelastic material which results in higher buckling loads of the energy harvesting material with smaller geometric arcs, i.e. smaller deformations, which increases the power output of the energy harvesting material. The use of a staggered wall contact in the form of the curved edge 642 achieves a higher spring constant. Sleeve 612 is also provided with a curved C-shaped slot 644 which concentrates the force of the energy harvesting material to the centre of the sleeve 612.

Referring to FIG. 12 sleeve 712 is illustrated which is provided with a staggered triangular edge 742, 746 which increases the pressure exerted onto the resilient material. This increased pressure alters the spring stiffness of the resilient material, particularly where the resilient material is a hyperelastic material which results in higher buckling loads of the energy harvesting material with smaller geometric arcs, i.e. smaller deformations, which increases the power output of the energy harvesting material. The use of a staggered wall contact in the form of the staggered triangular edge 742, 746 achieves a higher spring constant. Sleeve 712 is also provided with a square C-shaped slot 744 for ease of locating the energy harvesting material.

The length of the resilient material 14A, 14B is substantially the same as the length of sleeve 12A, 12B which is substantially the same as the length of sleeve clamp 24A, 24B and which is also preferably substantially the same length of energy harvesting material 18, such that the energy harvesting material 18 is fully supported.

In order to mount the energy harvesting material 18 within the energy generator support 16, one length of the energy harvesting material 18 is located in one of the sleeves 12A, 12B the two parts 16A, 16B, of the energy generator support 16 are then connected together with the opposite length of the energy harvesting material being located in the other of the sleeves 12A, 12B.

When the energy harvesting material 18 is mounted within the energy generator support 16, the two parts 16A, 16B essentially clamp the energy harvesting material 18 in position. In doing so the energy harvesting material 18 becomes deformed into its first position. The energy harvesting material 18 is somewhat flexible and as the two parts 16A, 16B of the energy harvesting material 18 are brought together the distance between the sleeves 12A, 12B, within which the energy harvesting material 18 is located, decreases to a point where the distance is less than the width of the energy harvesting material 18 resulting in the energy harvesting material 18 becoming deformed into its first position. In order to prevent the two parts 16A, 16B of the energy generator support 16, being brought too closely together so that the distance between the sleeves 12A, 12B within which the energy harvesting material 18 is located decreases to a point where the distance is substantially less than the width of the energy harvesting material 18 resulting in the energy harvesting material 18 breaking, the two parts 16A, 16B of the energy generator support 16 are each provided with two arms 26A, 26B, 26C, 26D. The arms 26A, 26B, 26C, 26D extend from the two parts 16A, 16B, in the same plane as the energy harvesting material 18. The arms 26A, 26B of part 16A mirror the arms 26C, 26D of part 16B, arm 26A of part 16A is arranged opposite arm 26C of part 16B, and arm 26B of part 16A is arranged opposite arm 26D of part 16B. As the two parts 16A, 16B are connected together the opposite arms 26A, 26B, 26C, 26D of the two parts 16A, 16B will butt against each other to prevent the two parts 16A, 16B from being brought closer together and to prevent the distance between the sleeves 12A, 12B within which the energy harvesting material 18 is located decreasing to a point where the distance is substantially less than the width of the energy harvesting material 18 which would result in the energy harvesting material 18 breaking.

The length of the sleeves 12A, 12B needs to be equal to or greater than the corresponding dimension of the energy harvesting material 18. The height of the sleeves 12A, 12B must be a sliding fit into the sleeve clamps 26A, 26B of the energy generator support 16 and the slot which houses the energy harvesting material 18 should be an interference fit with the energy harvesting material 18. The energy harvesting system 10 can vary in dimensions. In the embodiment illustrated the sleeves 12A, 12B are about 3 mm in height, about 26 mm in length and about 3 mm in depth, wherein the slot which houses the energy harvesting material 18 is about 0.8 mm high in the centre of the sleeve 12A, 12B and about 1.5 mm in depth.

In the embodiment illustrated shortened walls 28A, 28B, 28C, 28D or cut outs are provided in the external corners of the two parts 16A, 16B of the energy generator support 16. The shortened walls 28A, 28B, 28C, 28D or cut outs help to reduce the overall size of the energy harvesting system 10 and also reduce stress on the edges of the energy generator support 16.

The energy harvesting system 10 operates such that when a force is applied to the energy harvesting material 18, the energy harvesting material 18 moves from a pre-deformed first position to a second position, resilient material 14A, 14B assists in this movement and the sleeves 12A, 2B prevent the energy harvesting material 18 from damaging the resilient material 14A, 14B, and wherein when the force is removed from the energy harvesting material 18, the energy harvesting material 18 moves to the original pre-deformed first position.

FIG. 4 illustrates a second embodiment of an energy harvesting system 110 according to the present invention. The harvesting system 110 has an energy generator support 116 which is formed in two parts 116A, 116B which are connected together through the use of clamping bolts 120A, 120B which pass through corresponding apertures (not illustrated) provided in the two parts 116A, 116B of the energy generator support 116. The clamping bolts 120A, 120B are secured in place using nuts 122A, 122B, in the embodiment illustrated the nuts 122A, 122B are M1.8 nuts and the clamping bolts 120A, 120B are M1.8 bolts of 40 mm length. The size of the clamping bolts and nuts which are suitable for use will depend on the size of the energy generator support. In the alternative to a nut and bolt arrangement the two parts 116A, 116B of the energy generator support 116 may instead be connected together by screws, split pins, pop rivets or welding. In the case of pop rivets or welding the connection would be permanent.

The two parts 116A, 116B of the energy generator support 116, provide mounting supports between which energy harvesting material 118 is mounted. In the embodiment illustrated the energy harvesting material 118 is a piezoelectric transducer, in the embodiment illustrated there is a single piezoelectric transducer, in the alternative there may be a plurality of piezoelectric transducers stacked on top of one another.

Where a plurality of piezoelectric transducers are provided which are stacked on top of one another in order for the piezoelectric transducers to operate as a single energy harvesting material they need to be clamped together as illustrated in FIGS. 8 and 9. FIGS. 8 and 9 illustrate the use of 3 piezoelectric transducers 418A, 418B, 418C to form energy harvesting material 418. A clamping band 440 is provided to clamp the piezoelectric transducers 418A, 418B, 418C together to ensure that the electrical signal output from each of the piezoelectric transducers 418A, 418B, 418C is in phase and to improve the consistency and reliability. In the embodiment illustrated the clamping band 440 is an adhesive tape which is wound or wrapped around the piezoelectric transducers 418A, 418B, 418C. In an alternative the clamping band 440 is an adhesive cellulose tape, in a further alternative the clamping band 440 is formed from an injection moulded plastics material.

FIGS. 14 and 15 illustrate the use of 3 piezoelectric transducers 818A, 818B, 818C to form energy harvesting material 818. A clamping band 840 is provided to clamp the piezoelectric transducers 818A, 818B, 818C together to ensure that the electrical signal output from each of the piezoelectric transducers 818A, 818B, 818C is in phase and to improve the consistency and reliability. In the embodiment illustrated the clamping band 840 is an adhesive tape which is wound or wrapped around the piezoelectric transducers 818A, 818B, 818C. In an alternative the clamping band 840 is an adhesive cellulose tape, in a further alternative the clamping band 840 is formed from an injection moulded plastics material. A flexible upper electrode 850A, 850B, 850C and a resilient lower electrode 852A, 852B, 852C are provided for each of the piezoelectric transducers 818A, 818B, 818C wherein each of the piezoelectric transducers 818A, 818B, 818C is arranged between the upper 850A, 850B, 850C and lower electrodes 852A, 852B, 852C. The electrodes 850A, 850B, 850C, 852A, 852B, 852C allow the electrical charge generated to be captured and used to power electrical circuits or in the alternative be stored. In the embodiment illustrated the electrodes 850A, 850B, 850C, 852A, 852B, 852C comprise conductive copper tape which is adhered to the respective upper or lower surface of the piezoelectric material. Each flexible upper electrode 850A, 850B, 850C is provided with a layer of protective insulating material 854A, 854B, 854C, and each resilient lower electrode 852A, 852B, 852C is provided with a layer of protective insulating material 856A, 856B, 856C. The protective insulting material 854A, 854B, 854C, 856A, 856B, 856C ensures that there is no short between the electrodes 850A, 850B, 850C, 852A, 852B, 852C. The layer of protective insulating material 854A, 854B, 854C, 856A, 856B, 856C can simply be a plastic tape.

The two parts 116A, 116B of the energy generator support 116 which act as the mounting supports each have an internal surface (not shown) which is provided with a layer of resilient material 114A, 1148. In the embodiment illustrated the layer of resilient material 114A, 1148, is a metallic spring, such as a leaf spring or a laminated spring. The spring 114A, 1148 is used to reduce the buckling force and allow the energy harvesting material 118, in this case a piezoelectric transducer, to return to its original position.

The two parts 116A, 116B of the energy generator support 116 which act as the mounting supports each have a sleeve clamp 124A, 124B and are provided with a sleeve 112A, 112B. The sleeve 112A, 112B is formed from a non-resilient material such as a metallic material such as aluminium or steel or a plastics material such as polylactic acid (PLA) or acrylonitrile butadiene styrene (ABS), preferably where a metallic material is used the metallic material is provided with a coating of a non-conducting material such as a powder coating which also reduces the risk of corrosion of the sleeves 112A, 112B. The sleeve 112A, 112B is mounted onto the spring 114A, 114B. The sleeve 112A, 112B is then retained in position by sleeve clamp 124A, 124B which extends along both sides of the length of the sleeve 112A, 112B. In the embodiment illustrated the sleeve clamp 124A, 124B is formed integrally in each of the two parts 116A, 116B of the energy generator support 116. The sleeve 112A, 112B, is retained in position by sleeve clamp 124A, 124B such that it is able to move backwards and forwards in the same plane as the spring 114A, 114B, and the energy harvesting material 118, as energy harvesting material 118 and the spring 114A, 114B is deformed, but is not able to move in any other direction.

In the embodiment described sleeves 112A, 112B are generally a square C-shape. However, in the alternative the sleeve 112A, 112B may be other shapes as illustrated in FIGS. 10 to 12. Whilst these sleeves 512, 612, 712 are also generally C-shaped they have additional features.

Referring to FIG. 10 sleeve 512 is illustrated which is provided with a triangular edge 542 which increases the pressure exerted onto the resilient material. This increased pressure alters the spring stiffness of the resilient material, particularly where the resilient material is a hyperelastic material which results in higher buckling loads of the energy harvesting material with smaller geometric arcs, i.e. smaller deformations, which increases the power output of the energy harvesting material. The use of a staggered wall contact in the form of the triangular edge 542 achieves a higher spring constant. Sleeve 512 is also provided with a square C-shaped slot 544 for ease of locating the energy harvesting material.

Referring to FIG. 11 sleeve 612 is illustrated which is provided with a curved edge 642 which increases the pressure exerted onto the resilient material. This increased pressure alters the spring stiffness of the resilient material, particularly where the resilient material is a hyperelastic material which results in higher buckling loads of the energy harvesting material with smaller geometric arcs, i.e. smaller deformations, which increases the power output of the energy harvesting material. The use of a staggered wall contact in the form of the curved edge 642 achieves a higher spring constant. Sleeve 612 is also provided with a curved C-shaped slot 644 which concentrates the force of the energy harvesting material to the centre of the sleeve 612.

Referring to FIG. 12 sleeve 712 is illustrated which is provided with a staggered triangular edge 742, 746 which increases the pressure exerted onto the resilient material. This increased pressure alters the spring stiffness of the resilient material, particularly where the resilient material is a hyperelastic material which results in higher buckling loads of the energy harvesting material with smaller geometric arcs, i.e. smaller deformations, which increases the power output of the energy harvesting material. The use of a staggered wall contact in the form of the staggered triangular edge 742, 746 achieves a higher spring constant. Sleeve 712 is also provided with a square C-shaped slot 744 for ease of locating the energy harvesting material.

In order to mount the energy harvesting material 118 within the energy generator support 116, one length of the energy harvesting material 118 is located in one of the sleeves 112A, 112B the two parts 116A, 116B, of the energy generator support 116 are then connected together with the opposite length of the energy harvesting material 118 being located in the other of the sleeves 112A, 1128.

When the energy harvesting material 118 is mounted within the energy generator support 116, the two parts 116A, 116B essentially clamp the energy harvesting material 118 in position. In doing so the energy harvesting material 118 becomes deformed into its first position. The energy harvesting material 118 is somewhat flexible and as the two parts 116A, 116B of the energy harvesting material 118 are brought together the distance between the sleeves 112A, 112B, within which the energy harvesting material 118 is located, decreases to a point where the distance is less than the width of the energy harvesting material 118 resulting in the energy harvesting material 118 becoming deformed into its first position. In order to prevent the two parts 116A, 116B of the energy generator support 116, being brought too closely together so that the distance between the sleeves 112A, 112B within which the energy harvesting material 118 is located decreases to a point where the distance is substantially less than the width of the energy harvesting material 118 resulting in the energy harvesting material 118 breaking, the two parts 116A, 116B of the energy generator support 116 are each provided with two arms 126A, 126B, 126C, 126D. The arms 126A, 126B, 126C, 126D extend from the two parts 116A, 116B, in the same plane as the energy harvesting material 118. The arms 126A, 126B of part 116A mirror the arms 126C, 126D of part 116B, arm 126A of part 116A is arranged opposite arm 126C of part 116B, and arm 126B of part 116A is arranged opposite arm 126D of part 116B. As the two parts 116A, 116B are connected together the opposite arms 126A, 126B, 126C, 126D of the two parts 116A, 116B will butt against each other to prevent the two parts 116A, 116B from being brought closer together and to prevent the distance between the sleeves 112A, 1128 within which the energy harvesting material 118 is located decreasing to a point where the distance is substantially less than the width of the energy harvesting material 118 which would result in the energy harvesting material 118 breaking.

The length of the sleeves 112A, 112B needs to be equal to or greater than the corresponding dimension of the energy harvesting material 118. The height of the sleeves 112A, 1128 must be a sliding fit into the sleeve clamps 126A, 126B of the energy generator support 116 and the slot which houses the energy harvesting material 118 should be an interference fit with the energy harvesting material 118. The energy harvesting system 110 can vary in dimensions. In the embodiment illustrated the sleeves 112A, 112B are about 3 mm in height, about 26 mm in length and about 3 mm in depth, wherein the slot which houses the energy harvesting material 118 is about 0.8 mm high in the centre of the sleeve 112A, 1128 and about 1.5 mm in depth.

In the embodiment illustrated shortened walls 128A, 128B, 128C, 128D or cut outs are provided in the external corners of the two parts 116A, 116B of the energy generator support 116. The shortened walls 128A, 128B, 128C, 128D or cut outs help to reduce the overall size of the energy harvesting system 110 and also reduce stress on the edges of the energy generator support 116.

The energy harvesting system 110 operates such that when a force is applied to the energy harvesting material 118, the energy harvesting material 118 moves from a pre-deformed first position to a second position, spring 114A, 1148 assists in this movement and the sleeves 112A, 1128 prevent the energy harvesting material 118 from damaging or slipping off the spring 114A, 114B, and wherein when the force is removed from the energy harvesting material 118, the energy harvesting material 118 moves to the original pre-deformed first position.

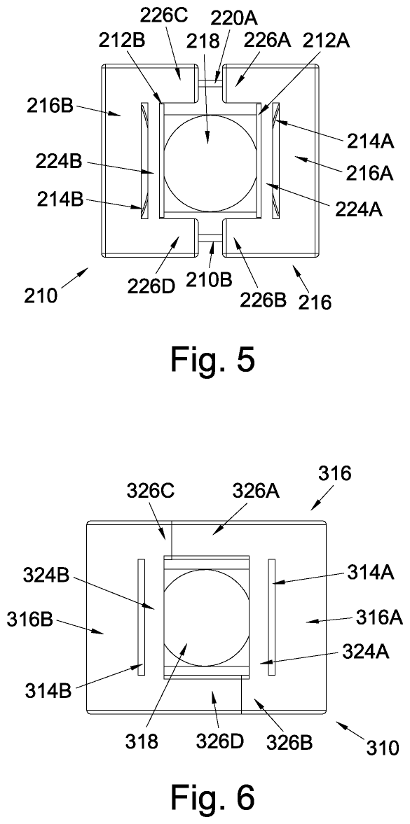

FIG. 5 illustrates a third embodiment of an energy harvesting system 210 according to the present invention. The harvesting system 210 has an energy generator support 216 which is formed in two parts 216A, 216B which are connected together through the use of clamping bolts 220A, 220B which pass through corresponding apertures (not illustrated) provided in the two parts 216A, 216B of the energy generator support 216. The clamping bolts 220A, 220B are secured in place using nuts 222A, 222B (not shown), in the embodiment illustrated the nuts 222A, 222B are M1.8 nuts and the clamping bolts 220A, 220B are M1.8 bolts of 40 mm length. The size of the clamping bolts and nuts which are suitable for use will depend on the size of the energy generator support. In the alternative to a nut and bolt arrangement the two parts 216A, 216B of the energy generator support 216 may instead be connected together by screws, split pins, pop rivets or welding. In the case of pop rivets or welding the connection would be permanent.

The two parts 216A, 216B of the energy generator support 216, provide mounting supports between which energy harvesting material 218 is mounted. In the embodiment illustrated the energy harvesting material 218 is a piezoelectric transducer, in the embodiment illustrated there is a single piezoelectric transducer, in the alternative there may be a plurality of piezoelectric transducers stacked on top of one another.

Where a plurality of piezoelectric transducers are provided which are stacked on top of one another in order for the piezoelectric transducers to operate as a single energy harvesting material they need to be clamped together as illustrated in FIGS. 8 and 9. FIGS. 8 and 9 illustrate the use of 3 piezoelectric transducers 418A, 418B, 418C to form energy harvesting material 418. A clamping band 440 is provided to clamp the piezoelectric transducers 418A, 418B, 418C together to ensure that the electrical signal output from each of the piezoelectric transducers 418A, 418B, 418C is in phase and to improve the consistency and reliability. In the embodiment illustrated the clamping band 440 is an adhesive tape which is wound or wrapped around the piezoelectric transducers 418A, 418B, 418C. In an alternative the clamping band 440 is an adhesive cellulose tape, in a further alternative the clamping band 440 is formed from an injection moulded plastics material.

FIGS. 14 and 15 illustrate the use of 3 piezoelectric transducers 818A, 818B, 818C to form energy harvesting material 818. A clamping band 840 is provided to clamp the piezoelectric transducers 818A, 818B, 818C together to ensure that the electrical signal output from each of the piezoelectric transducers 818A, 818B, 818C is in phase and to improve the consistency and reliability. In the embodiment illustrated the clamping band 840 is an adhesive tape which is wound or wrapped around the piezoelectric transducers 818A, 818B, 818C. In an alternative the clamping band 840 is an adhesive cellulose tape, in a further alternative the clamping band 840 is formed from an injection moulded plastics material. A flexible upper electrode 850A, 850B, 850C and a resilient lower electrode 852A, 852B, 852C are provided for each of the piezoelectric transducers 818A, 818B, 818C wherein each of the piezoelectric transducers 818A, 818B, 818C is arranged between the upper 850A, 850B, 850C and lower electrodes 852A, 852B, 852C. The electrodes 850A, 850B, 850C, 852A, 852B, 852C allow the electrical charge generated to be captured and used to power electrical circuits or in the alternative be stored. In the embodiment illustrated the electrodes 850A, 850B, 850C, 852A, 852B, 852C comprise conductive copper tape which is adhered to the respective upper or lower surface of the piezoelectric material. Each flexible upper electrode 850A, 850B, 850C is provided with a layer of protective insulating material 854A, 854B, 854C, and each resilient lower electrode 852A, 852B, 852C is provided with a layer of protective insulating material 856A, 856B, 856C. The protective insulting material 854A, 854B, 854C, 856A, 856B, 856C ensures that there is no short between the electrodes 850A, 850B, 850C, 852A, 852B, 852C. The layer of protective insulating material 854A, 854B, 854C, 856A, 856B, 856C can simply be a plastic tape.

The two parts 216A, 216B of the energy generator support 216 which act as the mounting supports each have an internal surface (not shown) which is provided with a layer of resilient material 214A, 214B. In the embodiment illustrated the layer of resilient material 214A, 214B, is a metallic spring, such as a leaf spring or a laminated spring. The spring 214A, 214B is used to reduce the buckling force and allow the energy harvesting material 218, in this case a piezoelectric transducer, to return to its original position. In the alternative layer of resilient material 214A, 214B may be silicone or another hyperelastic material.

The two parts 216A, 216B of the energy generator support 216 which act as the mounting supports each have a sleeve clamp 224A, 224B and are provided with a sleeve 212A, 212B. The sleeve 212A, 212B is formed from a non-resilient material such as a metallic material such as aluminium or steel or a plastics material such as polylactic acid (PLA) or acrylonitrile butadiene styrene (ABS), preferably where a metallic material is used the metallic material is provided with a coating of a non-conducting material such as a powder coating which also reduces the risk of corrosion of the sleeves 212A, 212B. The sleeve 212A, 212B, is mounted onto the spring 214A, 214B. The sleeve 212A, 212B is then retained in position by sleeve clamp 224A, 224B which extends along both sides of the length of the sleeve 212A, 212B. In the embodiment illustrated the sleeve clamp 224A, 224B is formed integrally in each of the two parts 216A, 216B of the energy generator support 216. The sleeve 212A, 212B, is retained in position by sleeve clamp 224A, 224B such that it is able to move backwards and forwards in the same plane as the spring 214A, 214B, and the energy harvesting material 218, as energy harvesting material 218 and the spring 214A, 214B is deformed, but is not able to move in any other direction.

In the embodiment described sleeves 212A, 212B are generally a square C-shape. However, in the alternative the sleeve 212A, 212B may be other shapes as illustrated in FIGS. 10 to 12. Whilst these sleeves 512, 612, 712 are also generally C-shaped they have additional features.

Referring to FIG. 10 sleeve 512 is illustrated which is provided with a triangular edge 542 which increases the pressure exerted onto the resilient material. This increased pressure alters the spring stiffness of the resilient material, particularly where the resilient material is a hyperelastic material which results in higher buckling loads of the energy harvesting material with smaller geometric arcs, i.e. smaller deformations, which increases the power output of the energy harvesting material. The use of a staggered wall contact in the form of the triangular edge 542 achieves a higher spring constant. Sleeve 512 is also provided with a square c shaped slot 544 for ease of locating the energy harvesting material.

Referring to FIG. 11 sleeve 612 is illustrated which is provided with a curved edge 642 which increases the pressure exerted onto the resilient material. This increased pressure alters the spring stiffness of the resilient material, particularly where the resilient material is a hyperelastic material which results in higher buckling loads of the energy harvesting material with smaller geometric arcs, i.e. smaller deformations, which increases the power output of the energy harvesting material. The use of a staggered wall contact in the form of the curved edge 642 achieves a higher spring constant. Sleeve 612 is also provided with a curved C-shaped slot 644 which concentrates the force of the energy harvesting material to the centre of the sleeve 612.

Referring to FIG. 12 sleeve 712 is illustrated which is provided with a staggered triangular edge 742, 746 which increases the pressure exerted onto the resilient material. This increased pressure alters the spring stiffness of the resilient material, particularly where the resilient material is a hyperelastic material which results in higher buckling loads of the energy harvesting material with smaller geometric arcs, i.e. smaller deformations, which increases the power output of the energy harvesting material. The use of a staggered wall contact in the form of the staggered triangular edge 742, 746 achieves a higher spring constant. Sleeve 712 is also provided with a square C-shaped slot 744 for ease of locating the energy harvesting material.

In order to mount the energy harvesting material 218 within the energy generator support 216, one length of the energy harvesting material 218 is located in one of the sleeves 212A, 212B the two parts 216A, 216B, of the energy generator support 216 are then connected together with the opposite length of the energy harvesting material 218 being located in the other of the sleeves 212A, 212B.

When the energy harvesting material 218 is mounted within the energy generator support 216, the two parts 216A, 216B essentially clamp the energy harvesting material 218 in position. In doing so the energy harvesting material 218 becomes deformed into its first position. The energy harvesting material 218 is somewhat flexible and as the two parts 216A, 216B of the energy harvesting material 218 are brought together the distance between the sleeves 212A, 212B, within which the energy harvesting material 218 is located, decreases to a point where the distance is less than the width of the energy harvesting material 218 resulting in the energy harvesting material 218 becoming deformed into its first position. In order to prevent the two parts 216A, 216B of the energy generator support 216, being brought too closely together so that the distance between the sleeves 212A, 212B within which the energy harvesting material 218 is located decreases to a point where the distance is substantially less than the width of the energy harvesting material 218 resulting in the energy harvesting material 218 breaking, the two parts 216A, 216B of the energy generator support 216 are each provided with two arms 226A, 226B, 226C, 226D. The arms 226A, 226B, 226C, 226D extend from the two parts 216A, 216B, in the same plane as the energy harvesting material 218. The arms 226A, 226B of part 216A mirror the arms 226C, 226D of part 216B, arm 226A of part 216A is arranged opposite arm 226C of part 216B, and arm 226B of part 216A is arranged opposite arm 226D of part 216B. As the two parts 216A, 216B are connected together the opposite arms 226A, 226B, 226C, 226D of the two parts 216A, 216B will butt against each other to prevent the two parts 216A, 216B from being brought closer together and to prevent the distance between the sleeves 212A, 212B within which the energy harvesting material 218 is located decreasing to a point where the distance is substantially less than the width of the energy harvesting material 218 which would result in the energy harvesting material 218 breaking.

The length of the sleeves 212A, 212B needs to be equal to or greater than the corresponding dimension of the energy harvesting material 218. The height of the sleeves 212A, 212B must be a sliding fit into the sleeve clamps 226A, 226B of the energy generator support 216 and the slot which houses the energy harvesting material 218 should be an interference fit with the energy harvesting material 218. The energy harvesting system 210 can vary in dimensions. In the embodiment illustrated the sleeves 212A, 212B are about 3 mm in height, about 26 mm in length and about 3 mm in depth, wherein the slot which houses the energy harvesting material 218 is about 0.8 mm high in the centre of the sleeve 212A, 212B and about 1.5 mm in depth.

In the embodiment illustrated shortened walls or cut outs are not provided in the external corners of the two parts 216A, 216B of the energy generator support 216. This provides fora more aesthetically pleasing energy harvesting system 210.

The energy harvesting system 210 operates such that when a force is applied to the energy harvesting material 218, the energy harvesting material 218 moves from a pre-deformed first position to a second position, spring 214A, 214B assists in this movement and the sleeves 212A, 212B prevent the energy harvesting material 218 from damaging or slipping off the spring 214A, 214B, and wherein when the force is removed from the energy harvesting material 218, the energy harvesting material 218 moves to the original pre-deformed first position.

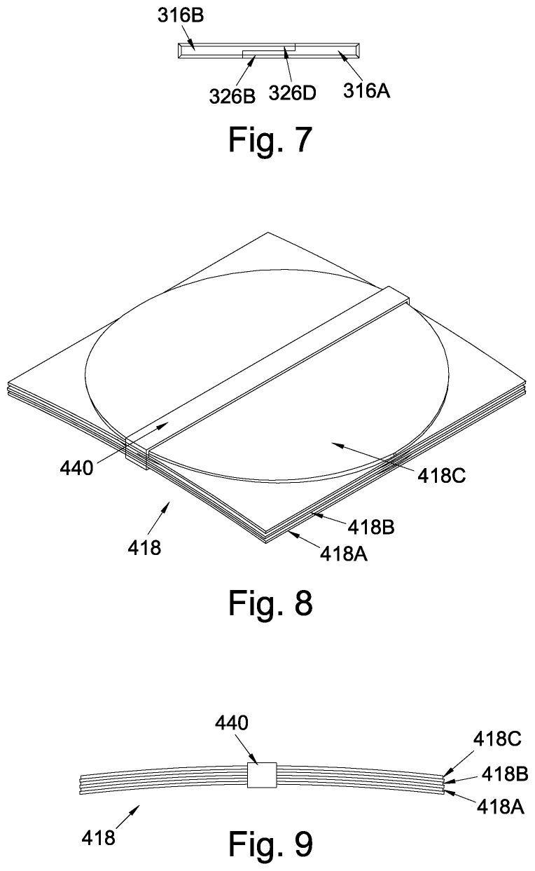

FIGS. 6 and 7 illustrate a fourth embodiment of an energy harvesting system 310 according to the present invention. The harvesting system 310 has an energy generator support 316 which is formed in two parts 316A, 316B which are connected together.

The two parts 316A, 316B of the energy generator support 316, provide mounting supports between which energy harvesting material 318 is mounted. In the embodiment illustrated the energy harvesting material 318 is a piezoelectric transducer, in the embodiment illustrated there is a single piezoelectric transducer, in the alternative there may be a plurality of piezoelectric transducers stacked on top of one another.

Where a plurality of piezoelectric transducers are provided which are stacked on top of one another in order for the piezoelectric transducers to operate as a single energy harvesting material they need to be clamped together as illustrated in FIGS. 8 and 9. FIGS. 8 and 9 illustrate the use of 3 piezoelectric transducers 418A, 418B, 418C to form energy harvesting material 418. A clamping band 440 is provided to clamp the piezoelectric transducers 418A, 418B, 418C together to ensure that the electrical signal output from each of the piezoelectric transducers 418A, 418B, 418C is in phase and to improve the consistency and reliability. In the embodiment illustrated the clamping band 440 is an adhesive tape which is wound or wrapped around the piezoelectric transducers 418A, 418B, 418C. In an alternative the clamping band 440 is an adhesive cellulose tape, in a further alternative the clamping band 440 is formed from an injection moulded plastics material.

FIGS. 14 and 15 illustrate the use of 3 piezoelectric transducers 818A, 818B, 818C to form energy harvesting material 818. A clamping band 840 is provided to clamp the piezoelectric transducers 818A, 818B, 818C together to ensure that the electrical signal output from each of the piezoelectric transducers 818A, 818B, 818C is in phase and to improve the consistency and reliability. In the embodiment illustrated the clamping band 840 is an adhesive tape which is wound or wrapped around the piezoelectric transducers 818A, 818B, 818C. In an alternative the clamping band 840 is an adhesive cellulose tape, in a further alternative the clamping band 840 is formed from an injection moulded plastics material. A flexible upper electrode 850A, 850B, 850C and a resilient lower electrode 852A, 852B, 852C are provided for each of the piezoelectric transducers 818A, 818B, 818C wherein each of the piezoelectric transducers 818A, 818B, 818C is arranged between the upper 850A, 850B, 850C and lower electrodes 852A, 852B, 852C. The electrodes 850A, 850B, 850C, 852A, 852B, 852C allow the electrical charge generated to be captured and used to power electrical circuits or in the alternative be stored. In the embodiment illustrated the electrodes 850A, 850B, 850C, 852A, 852B, 852C comprises conductive copper tape which is adhered to the respective upper or lower surface of the piezoelectric material. Each flexible upper electrode 850A, 850B, 850C is provided with a layer of protective insulating material 854A, 854B, 854C, and each resilient lower electrode 852A, 852B, 852C is provided with a layer of protective insulating material 856A, 856B, 856C. The protective insulting material 854A, 854B, 854C, 856A, 856B, 856C ensures that there is no short between the electrodes 850A, 850B, 850C, 852A, 852B, 852C. The layer of protective insulating material 854A, 854B, 854C, 856A, 856B, 856C can simply be a plastic tape.

When the energy harvesting material 318 is mounted within the energy generator support 316, the two parts 316A, 316B essentially clamp the energy harvesting material 318 in position. In doing so the energy harvesting material 318 becomes deformed into its first position. The energy harvesting material 318 is somewhat flexible and as the two parts 316A, 316B of the energy harvesting material 318 are brought together the distance between the sleeves (not shown), within which the energy harvesting material 318 is located, decreases to a point where the distance is less than the width of the energy harvesting material 318 resulting in the energy harvesting material 318 becoming deformed into its first position. In order to prevent the two parts 316A, 316B of the energy generator support 316, being brought too closely together so that the distance between the sleeves (not shown) within which the energy harvesting material 318 is located decreases to a point where the distance is substantially less than the width of the energy harvesting material 318 resulting in the energy harvesting material 318 breaking, the two parts 316A, 316B of the energy generator support 316 are each provided with two arms 326A, 326B, 326C, 326D. The arms 326A, 326B, 326C, 326D extend from the two parts 316A, 316B, in the same plane as the energy harvesting material 318. Arm 326A of part 316A is arranged opposite arm 326C of part 316B, and arm 326B of part 316A is arranged opposite arm 326D of part 316B. As the two parts 316A, 316B are connected together the opposite arms 326A, 326B, 326C, 326D of the two parts 316A, 316B will butt against each other to prevent the two parts 316A, 316B from being brought closer together and to prevent the distance between the sleeves (not shown) within which the energy harvesting material 318 is located decreasing to a point where the distance is substantially less than the width of the energy harvesting material 318 which would result in the energy harvesting material 318 breaking.

In the embodiment illustrated the arms 326A, 326B, 326C, 326D are provided such that not only do they butt against the opposite arm, but they also overlap with the opposite arm. As seen more clearly in FIG. 7 which shows a side view of the energy harvesting system 310 each of the arms 326B, 326D are of half the thickness of the overall thickness of each of the two parts 316A, 316B. This creates a greater surface area of contact between the arms 326B, 326D of the two parts 316A, 316B. By using this overlapping arrangement the two parts 316A, 316B, can be connected together using spot welding or adhesive for example correctly every time in a single pre-determined arrangement as there is only one way that the two parts 316A, 316B can be connected together. This ensures that the product cannot be tampered with and ensures that the energy harvesting material 318 remains in the same position which means that it is able to produce consistent power output through use over prolonged periods.

The length of the sleeves (not shown) needs to be equal to or greater than the corresponding dimension of the energy harvesting material 318. The height of the sleeves (not shown) must be a sliding fit into the sleeve clamps 326A, 326B of the energy generator support 316 and the slot which houses the energy harvesting material 318 should be an interference fit with the energy harvesting material 318. The energy harvesting system 310 can vary in dimensions. In the embodiment illustrated the sleeves (not shown) are about 3 mm in height, about 26 mm in length and about 3 mm in depth, wherein the slot which houses the energy harvesting material 318 is about 0.8 mm high in the centre of the sleeve (not shown) and about 1.5 mm in depth.

The two parts 316A, 316B of the energy generator support 316 which act as the mounting supports each have an internal surface (not shown) which is provided with a layer of resilient material 314A, 314B. In the embodiment illustrated the layer of resilient material 314A, 314B, is silicone rubber, in the alternative another hyperelastic material may be used, in another alternative the resilient material could be a spring, such as a leaf spring or a laminated spring. The layer of resilient material 314A, 314B is used to reduce the buckling force and allow the energy harvesting material 318, in this case a piezoelectric transducer, to return to its original position.

The two parts 316A, 316B of the energy generator support 316 which act as the mounting supports each have a sleeve clamp 324A, 324B and are provided with a sleeve (not shown). The sleeve (not shown) is formed from a non-resilient material such as a metallic material such as aluminium or steel or a plastics material such as polylactic acid (PLA) or acrylonitrile butadiene styrene (ABS), preferably where a metallic material is used the material is provided with a coating of non-conducting material such as a powder coating which also reduces the risk of corrosion of the sleeves (not shown). The sleeve (not shown) is mounted onto the layer of resilient material 314A, 314B. The sleeve (not shown) is then retained in position by sleeve clamp 324A, 324B which extends along both sides of the length of the sleeve (not shown). In the embodiment illustrated the sleeve clamp 324A, 324B is formed integrally in each of the two parts 316A, 316B of the energy generator support 316. The sleeve 312A, 312B, is retained in position by sleeve clamp 324A, 324B such that it is able to move backwards and forwards in the same plane as the resilient material 314A, 314B, and the energy harvesting material 318, as energy harvesting material 318 and the resilient material 314A, 314B is deformed, but is not able to move in any other direction.

In the embodiment described sleeves (not shown) are generally a square C-shape. However, in the alternative the sleeve (not shown) may be other shapes as illustrated in FIGS. 10 to 12. Whilst these sleeves 512, 612, 712 are also generally C-shaped they have additional features.

Referring to FIG. 10 sleeve 512 is illustrated which is provided with a triangular edge 542 which increases the pressure exerted onto the resilient material. This increased pressure alters the spring stiffness of the resilient material, particularly where the resilient material is a hyperelastic material which results in higher buckling loads of the energy harvesting material with smaller geometric arcs, i.e. smaller deformations, which increases the power output of the energy harvesting material. The use of a staggered wall contact in the form of the triangular edge 542 achieves a higher spring constant. Sleeve 512 is also provided with a square C-shaped slot 544 for ease of locating the energy harvesting material.

Referring to FIG. 11 sleeve 612 is illustrated which is provided with a curved edge 642 which increases the pressure exerted onto the resilient material. This increased pressure alters the spring stiffness of the resilient material, particularly where the resilient material is a hyperelastic material which results in higher buckling loads of the energy harvesting material with smaller geometric arcs, i.e. smaller deformations, which increases the power output of the energy harvesting material. The use of a staggered wall contact in the form of the curved edge 642 achieves a higher spring constant. Sleeve 612 is also provided with a curved C-shaped slot 644 which concentrates the force of the energy harvesting material to the centre of the sleeve 612.

Referring to FIG. 12 sleeve 712 is illustrated which is provided with a staggered triangular edge 742, 746 which increases the pressure exerted onto the resilient material. This increased pressure alters the spring stiffness of the resilient material, particularly where the resilient material is a hyperelastic material which results in higher buckling loads of the energy harvesting material with smaller geometric arcs, i.e. smaller deformations, which increases the power output of the energy harvesting material. The use of a staggered wall contact in the form of the staggered triangular edge 742, 746 achieves a higher spring constant. Sleeve 712 is also provided with a square C-shaped slot 744 for ease of locating the energy harvesting material.

The length of the resilient material 314A, 314B is substantially the same as the length of sleeve (not shown) which is substantially the same as the length of sleeve clamp 324A, 324B and which is also preferably substantially the same length of energy harvesting material 318, such that the energy harvesting material 318 is fully supported.

In order to mount the energy harvesting material 318 within the energy generator support 316, one length of the energy harvesting material 318 is located in one of the sleeves (not shown) the two parts 316A, 316B, of the energy generator support 316 are then connected together with the opposite length of the energy harvesting material being located in the other of the sleeves (not shown).

In the embodiment illustrated shortened walls or cut outs are not provided in the external corners of the two parts. This provides for a more aesthetically pleasing energy harvesting system 310.

The energy harvesting system 310 operates such that when a force is applied to the energy harvesting material 318, the energy harvesting material 318 moves from a pre-deformed first position to a second position, resilient material 314A, 314B assists in this movement and the sleeves (not shown) prevent the energy harvesting material 318 from damaging the resilient material 314A, 314B, and wherein when the force is removed from the energy harvesting material 318, the energy harvesting material 318 moves to the original pre-deformed first position.

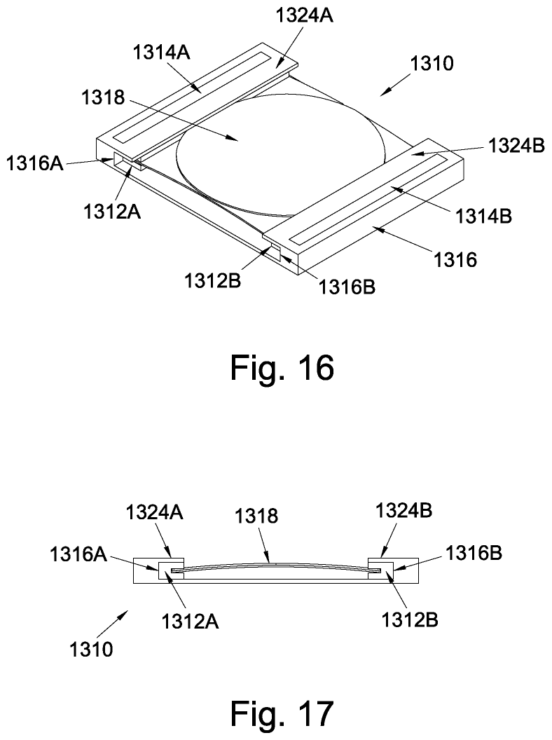

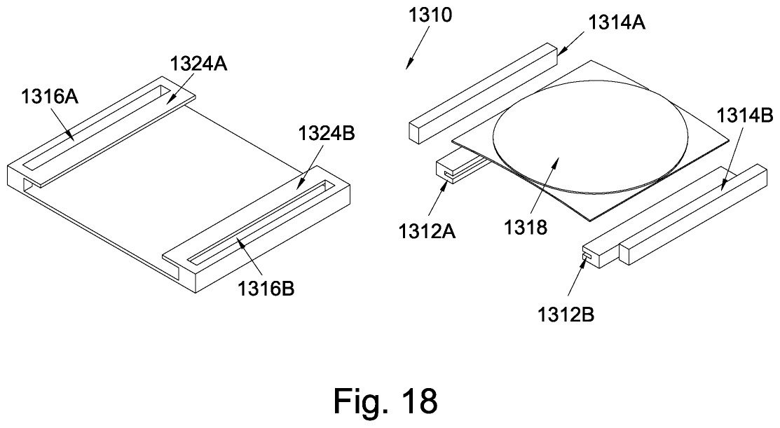

FIGS. 16 to 18 illustrate a fifth embodiment of an energy harvesting system 1310 according to the present invention. The harvesting system 1310 has an energy generator support 1316 which is formed in as a single portion. The energy generator support 1316 may be formed as a single portion through moulding, extrusion or 3D printing for example. Where the energy generator support 1316 is formed from an extrusion in particular the length of the extrusion can be varied depending on the number of energy harvesting systems required.

The energy generator support 1316, provides mounting supports 1317A, 1317B between which energy harvesting material 1318 is mounted. In one alternative the mounting supports 1316A, 1316B may be provided with a recess or pocket.

In the embodiment illustrated the energy harvesting material 1318 is a piezoelectric transducer, in the embodiment illustrated there is a single piezoelectric transducer, in the alternative there may be a plurality of piezoelectric transducers stacked on top of one another.

Where a plurality of piezoelectric transducers are provided which are stacked on top of one another in order for the piezoelectric transducers to operate as a single energy harvesting material they need to be clamped together as illustrated in FIGS. 8 and 9. FIGS. 8 and 9 illustrate the use of 3 piezoelectric transducers 418A, 418B, 418C to form energy harvesting material 418. A clamping band 440 is provided to clamp the piezoelectric transducers 418A, 418B, 418C together to ensure that the electrical signal output from each of the piezoelectric transducers 418A, 418B, 418C is in phase and to improve the consistency and reliability. In the embodiment illustrated the clamping band 440 is an adhesive tape which is wound or wrapped around the piezoelectric transducers 418A, 418B, 418C. In an alternative the clamping band 440 is an adhesive cellulose tape, in a further alternative the clamping band 440 is formed from an injection moulded plastics material.

FIGS. 14 and 15 illustrate the use of 3 piezoelectric transducers 818A, 818B, 818C to form energy harvesting material 818. A clamping band 840 is provided to clamp the piezoelectric transducers 818A, 818B, 818C together to ensure that the electrical signal output from each of the piezoelectric transducers 818A, 818B, 818C is in phase and to improve the consistency and reliability. In the embodiment illustrated the clamping band 840 is an adhesive tape which is wound or wrapped around the piezoelectric transducers 818A, 818B, 818C. In an alternative the clamping band 840 is an adhesive cellulose tape, in a further alternative the clamping band 840 is formed from an injection moulded plastics material. A flexible upper electrode 850A, 850B, 850C and a resilient lower electrode 852A, 852B, 852C are provided for each of the piezoelectric transducers 818A, 818B, 818C wherein each of the piezoelectric transducers 818A, 818B, 818C is arranged between the upper 850A, 850B, 850C and lower electrodes 852A, 852B, 852C. The electrodes 850A, 850B, 850C, 852A, 852B, 852C allow the electrical charge generated to be captured and used to power electrical circuits or in the alternative be stored. In the embodiment illustrated the electrodes 850A, 850B, 850C, 852A, 852B, 852C comprise conductive copper tape which is adhered to the respective upper or lower surface of the piezoelectric material. Each flexible upper electrode 850A, 850B, 850C is provided with a layer of protective insulating material 854A, 854B, 854C, and each resilient lower electrode 852A, 852B, 852C is provided with a layer of protective insulating material 856A, 856B, 856C. The protective insulting material 854A, 854B, 854C, 856A, 856B, 856C ensures that there is no short between the electrodes 850A, 850B, 850C, 852A, 852B, 852C. The layer of protective insulating material 854A, 854B, 854C, 856A, 856B, 856C can simply be a plastic tape.

The mounting supports 1317A, 1317B of the energy generator support 1316 each have a surface which is provided with a layer of resilient material 1314A, 1314B. In the embodiment illustrated the layer of resilient material 1314A, 1314B, is silicone rubber, in the alternative another hyperelastic material may be used, in another alternative the resilient material could be a spring, such as a leaf spring or a laminated spring. The layer of resilient material 1314A, 1314B is used to reduce the buckling force and allow the energy harvesting material 1318, in this case a piezoelectric transducer, to return to its original position.

The mounting supports 1316A, 1316B of the energy generator support 1316 each have a sleeve clamp 1324A, 1324B and are provided with a sleeve 1312A, 1312B. The sleeve 1312A, 1312B is formed from a non-resilient material such as a metallic material such as aluminium or steel or a plastics material such as polylactic acid (PLA) or acrylonitrile butadiene styrene (ABS), preferably where a metallic material is used the metallic material is provided with a coating of a non-conducting material such as a powder coating which also reduces the risk of corrosion of the sleeves 1312A, 1312B. The sleeve 1312A, 1312B is mounted onto the resilient material 1314A, 1314B. The sleeve 1312A, 1312B is then retained in position by sleeve clamp 1324A, 1324B which extends along both sides of the length of the sleeve 1312A, 1312B. In the embodiment illustrated the sleeve clamp 1324A, 1324B is formed integrally with the energy generator support 1316. The sleeve 1312A, 1312B, is retained in position by sleeve clamp 1324A, 1324B such that it is able to move backwards and forwards in the same plane as the resilient material 1314A, 1314B, and the energy harvesting material 1318, as energy harvesting material 1318 and the resilient material 1314A, 1314B are deformed, but is not able to move in any other direction.

In the embodiment described sleeves 1312A, 1312B are generally a square C-shape. However, in the alternative the sleeve 1312A, 1312B may be other shapes as illustrated in FIGS. 10 to 12. Whilst these sleeves 512, 612, 712 are also generally C-shaped they have additional features.

Referring to FIG. 10 sleeve 512 is illustrated which is provided with a triangular edge 542 which increases the pressure exerted onto the resilient material. This increased pressure alters the spring stiffness of the resilient material, particularly where the resilient material is a hyperelastic material which results in higher buckling loads of the energy harvesting material with smaller geometric arcs, i.e. smaller deformations, which increases the power output of the energy harvesting material. The use of a staggered wall contact in the form of the triangular edge 542 achieves a higher spring constant. Sleeve 512 is also provided with a square C-shaped slot 544 for ease of locating the energy harvesting material.

Referring to FIG. 11 sleeve 612 is illustrated which is provided with a curved edge 642 which increases the pressure exerted onto the resilient material. This increased pressure alters the spring stiffness of the resilient material, particularly where the resilient material is a hyperelastic material which results in higher buckling loads of the energy harvesting material with smaller geometric arcs, i.e. smaller deformations, which increases the power output of the energy harvesting material. The use of a staggered wall contact in the form of the curved edge 642 achieves a higher spring constant. Sleeve 612 is also provided with a curved C-shaped slot 644 which concentrates the force of the energy harvesting material to the centre of the sleeve 612.

Referring to FIG. 12 sleeve 712 is illustrated which is provided with a staggered triangular edge 742, 746 which increases the pressure exerted onto the resilient material. This increased pressure alters the spring stiffness of the resilient material, particularly where the resilient material is a hyperelastic material which results in higher buckling loads of the energy harvesting material with smaller geometric arcs, i.e. smaller deformations, which increases the power output of the energy harvesting material. The use of a staggered wall contact in the form of the staggered triangular edge 742, 746 achieves a higher spring constant. Sleeve 712 is also provided with a square C-shaped slot 744 for ease of locating the energy harvesting material.

In order to mount the energy harvesting material 1318 within the energy generator support 1316, the energy harvesting material 1318 is located in both of the end of sleeves 1312A, 1312B by deforming the energy harvesting material 1318 and then slid into position in the energy harvesting material's 1318 first position.

The length of the sleeves 1312A, 1312B needs to be equal to or greater than the corresponding dimension of the energy harvesting material 1318. The height of the sleeves 1312A, 1312B must be a sliding fit into the sleeve clamps 1326A, 1326B of the energy generator support 1316 and the slot which houses the energy harvesting material 1318 should be an interference fit with the energy harvesting material 1318. The energy harvesting system 1310 can vary in dimensions. In the embodiment illustrated the sleeves 1312A, 1312B are about 3 mm in height, about 26 mm in length and about 3 mm in depth, wherein the slot which houses the energy harvesting material 1318 is about 0.8 mm high in the centre of the sleeve 1312A, 1312B and about 1.5 mm in depth the particular dimensions can be tailored to achieve a desired power out or input force.

The energy harvesting system 1310 operates such that when a force is applied to the energy harvesting material 1318, the energy harvesting material 1318 moves from a pre-deformed first position to a second position, resilient material 1314A, 1314B assists in this movement and the sleeves 1312A, 1312B prevent the energy harvesting material 1318 from damaging or slipping off the resilient material 1314A, 1314B, and wherein when the force is removed from the energy harvesting material 1318, the energy harvesting material 1318 moves to the original pre-deformed first position.

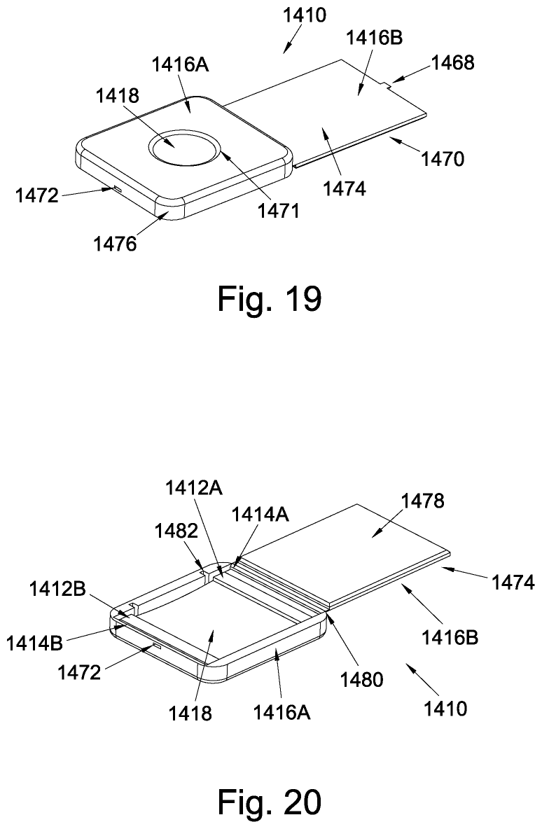

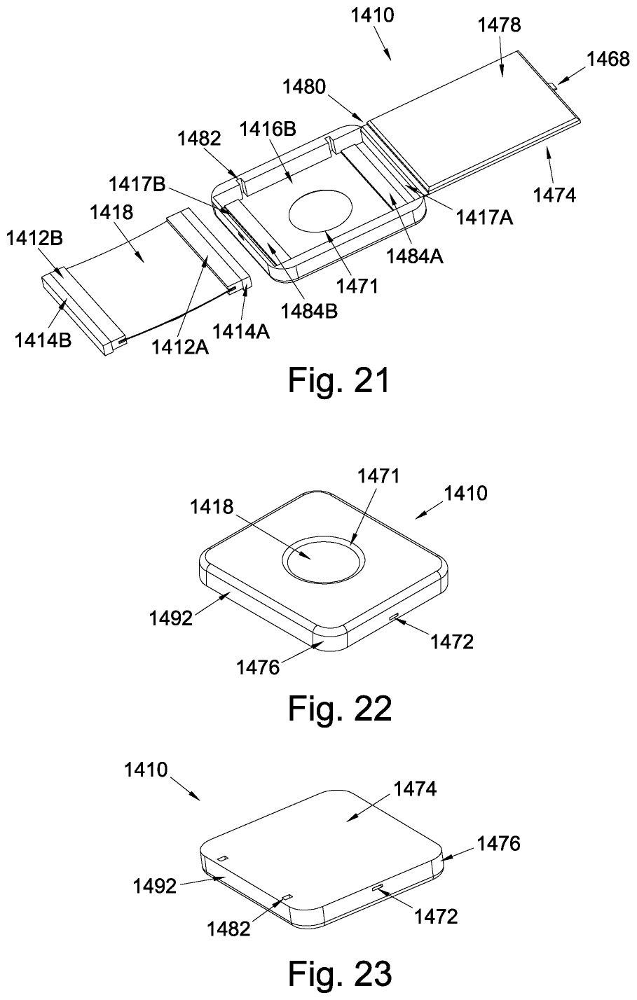

FIGS. 19 to 23 illustrate a sixth embodiment of an energy harvesting system 1410 according to the present invention. The energy harvesting system 1410 has an energy generator support 1416 which is formed in two parts 1416A, 1416B which are connected together. In the embodiment illustrated the two parts 1416A, 1416B are connected together with a living hinge 1480. The two parts 1416A, 1416B of the energy generator support 1416 and living hinge 1480 can be integrally formed through moulding or 3D printing for example. In another alternative the two parts 1416A, 1416B of the energy generator support 1416 may be separate machined components which are connected together on assembly to form the energy generator support 1416.

The first part 1416A of the energy generator support 1416 provides mounting supports 1417A, 1417B between which energy harvesting material 1418 is mounted, and a portion 1478 of the second part 1416B of the energy generator support 1416 along with a portion 1484A, 1484B of the first part 1416A of the energy generator support 1416 act together to form a sleeve clamp when the energy harvesting system 1410 is assembled to retain the energy harvesting material 1418 in position as discussed in more detail below.

In the embodiment illustrated the energy harvesting material 1418 is a piezoelectric transducer, in the embodiment illustrated there is a single piezoelectric transducer, in the alternative there may be a plurality of piezoelectric transducers stacked on top of one another.

Where a plurality of piezoelectric transducers are provided which are stacked on top of one another in order for the piezoelectric transducers to operate as a single energy harvesting material they need to be clamped together as illustrated in FIGS. 8 and 9. FIGS. 8 and 9 illustrate the use of 3 piezoelectric transducers 418A, 418B, 418C to form energy harvesting material 418. A clamping band 440 is provided to clamp the piezoelectric transducers 418A, 418B, 418C together to ensure that the electrical signal output from each of the piezoelectric transducers 418A, 418B, 418C is in phase and to improve the consistency and reliability. In the embodiment illustrated the clamping band 440 is an adhesive tape which is wound or wrapped around the piezoelectric transducers 418A, 418B, 418C. In an alternative the clamping band 440 is an adhesive cellulose tape, in a further alternative the clamping band 440 is formed from an injection moulded plastics material.

FIGS. 14 and 15 illustrate the use of 3 piezoelectric transducers 818A, 818B, 818C to form energy harvesting material 818. A clamping band 840 is provided to clamp the piezoelectric transducers 818A, 818B, 818C together to ensure that the electrical signal output from each of the piezoelectric transducers 818A, 818B, 818C is in phase and to improve the consistency and reliability. In the embodiment illustrated the clamping band 840 is an adhesive tape which is wound or wrapped around the piezoelectric transducers 818A, 818B, 818C. In an alternative the clamping band 840 is an adhesive cellulose tape, in a further alternative the clamping band 840 is formed from an injection moulded plastics material. A flexible upper electrode 850A, 850B, 850C and a resilient lower electrode 852A, 852B, 852C are provided for each of the piezoelectric transducers 818A, 818B, 818C wherein each of the piezoelectric transducers 818A, 818B, 818C is arranged between the upper 850A, 850B, 850C and lower electrodes 852A, 852B, 852C. The electrodes 850A, 850B, 850C, 852A, 852B, 852C allow the electrical charge generated to be captured and used to power electrical circuits or in the alternative be stored. In the embodiment illustrated the electrodes 850A, 850B, 850C, 852A, 852B, 852C comprise conductive copper tape which is adhered to the respective upper or lower surface of the piezoelectric material. Each flexible upper electrode 850A, 850B, 850C is provided with a layer of protective insulating material 854A, 854B, 854C, and each resilient lower electrode 852A, 852B, 852C is provided with a layer of protective insulating material 856A, 856B, 856C. The protective insulting material 854A, 854B, 854C, 856A, 856B, 856C ensures that there is no short between the electrodes 850A, 850B, 850C, 852A, 852B, 852C. The layer of protective insulating material 854A, 854B, 854C, 856A, 856B, 856C can simply be a plastic tape.

The mounting supports 1417A, 1417B of the first part 1416A of the energy generator support 1416 each have an internal surface which is provided with a layer of resilient material 1414A, 1414B. In the embodiment illustrated the layer of resilient material 1414A, 1414B, is silicone rubber, in the alternative another hyperelastic material may be used, in another alternative the resilient material could be a spring, such as a leaf spring or a laminated spring. The layer of resilient material 1414A, 1414B is used to reduce the buckling force and allow the energy harvesting material 1418, in this case a piezoelectric transducer, to return to its original position.

The mounting supports 1417A, 1417B of the energy generator support 1416 are each provided with a sleeve 1412A, 1412B and a portion 1478 of the second part 1416B of the energy generator support 1416 along with a portion 1484A, 184B of the first part 1416A of the energy generator support 1416 act together to form sleeve clamps (not illustrated) when the energy harvesting system 1410 is assembled to retain the energy harvesting material 1418 in position. The sleeve 1412A, 1412B is formed from a non-resilient material such as a metallic material such as aluminium or steel or a plastics material such as polylactic acid (PLA) or acrylonitrile butadiene styrene (ABS), preferably where a metallic material is used the metallic material is provided with a coating of a non-conducting material such as a powder coating which also reduces the risk of corrosion of the sleeves 1412A, 1412B. The sleeve 1412A, 1412B is mounted onto the resilient material 1414A, 1414B. The sleeve 1412A, 1412B is then retained in position by the sleeve clamps which are formed along both sides of the length of the sleeve 1412A, 1412B.

In the embodiment illustrated the sleeve clamp is formed integrally with the energy generator support 1416 by a portion 1478 of the second part 1416B of the energy generator support 1416 along with a portion 1484A, 184B of the first part 1416A of the energy generator support 1416 which act together to form sleeve clamp when the energy harvesting system 1410 is assembled to retain sleeve 1412A, 1412B and the energy harvesting material 1418 in position. The sleeve 1412A, 1412B, is retained in position by the sleeve clamp formed such that the sleeve 1412A, 1412B is able to move backwards and forwards in the same plane as the resilient material 1414A, 1414B, and the energy harvesting material 1418, as energy harvesting material 1418 and the resilient material 1414A, 1414B are deformed, but is not able to move in any other direction.

In the embodiment described sleeves 1412A, 1412B are generally a square C-shape. However, in the alternative the sleeve 1412A, 1412B may be other shapes as illustrated in FIGS. 10 to 12. Whilst these sleeves 512, 612, 712 are also generally C-shaped they have additional features.

Referring to FIG. 10 sleeve 512 is illustrated which is provided with a triangular edge 542 which increases the pressure exerted onto the resilient material. This increased pressure alters the spring stiffness of the resilient material, particularly where the resilient material is a hyperelastic material which results in higher buckling loads of the energy harvesting material with smaller geometric arcs, i.e. smaller deformations, which increases the power output of the energy harvesting material. The use of a staggered wall contact in the form of the triangular edge 542 achieves a higher spring constant. Sleeve 512 is also provided with a square C-shaped slot 544 for ease of locating the energy harvesting material.

Referring to FIG. 11 sleeve 612 is illustrated which is provided with a curved edge 642 which increases the pressure exerted onto the resilient material. This increased pressure alters the spring stiffness of the resilient material, particularly where the resilient material is a hyperelastic material which results in higher buckling loads of the energy harvesting material with smaller geometric arcs, i.e. smaller deformations, which increases the power output of the energy harvesting material. The use of a staggered wall contact in the form of the curved edge 642 achieves a higher spring constant. Sleeve 612 is also provided with a curved C-shaped slot 644 which concentrates the force of the energy harvesting material to the centre of the sleeve 612.

Referring to FIG. 12 sleeve 712 is illustrated which is provided with a staggered triangular edge 742, 746 which increases the pressure exerted onto the resilient material. This increased pressure alters the spring stiffness of the resilient material, particularly where the resilient material is a hyperelastic material which results in higher buckling loads of the energy harvesting material with smaller geometric arcs, i.e. smaller deformations, which increases the power output of the energy harvesting material. The use of a staggered wall contact in the form of the staggered triangular edge 742, 746 achieves a higher spring constant. Sleeve 712 is also provided with a square C-shaped slot 744 for ease of locating the energy harvesting material.

In order to mount the energy harvesting material 1418 within the energy generator support 1416 the layer of resilient material 1414A, 1414B is positioned on mounting supports 1417A, 1417B in the first part 1416A of the energy generator support 1416 then the energy harvesting material 1418 is located sleeves 1412A, 1412B and then placed into position between the layer of resilient material 1414A, 1414B before the second part 1416B of the energy generator support 1416 is put into position to clamp sleeves 1412A, 1412B and retain energy harvesting material 1418 in position. Essentially the two portions 1416A and 1416B of the energy generator support 1416 are formed from a single injection mould that once closed creates the structural support, and environmental protection for the energy harvester 1418. To clamp the energy harvester 1418, it must first be protected by its located sleeves 1412A and 1412B following this a layer of resilient material 1414A, 1414B must be used to against the internal walls of the mounting supports 1417A, 1417B. A press fit ensures ease of fitting for manufacturing purposes and ensures an optimised size.

The length of the sleeves 1412A, 1412B needs to be equal to or greater than the corresponding dimension of the energy harvesting material 1418. The height of the sleeves 1412A, 1412B must be an interference fit into the sleeve clamps formed by the two parts 1416A, 1416B of the energy generator support 1416 and the slot which houses the energy harvesting material 1418 should be an interference fit with the energy harvesting material 1418. In one embodiment the sleeves 1412A, 1412B are grooved with an interference fit, to securely house the energy harvesting material 1418. A profile is used, 1484A and 1484B, to provide a top clamp for the sleeves to reduce movement and fatigue of the system. The energy harvesting system 1410 can vary in dimensions. In the embodiment illustrated the sleeves 1412A, 1412B are about 3 mm in height, about 26 mm in length and about 3 mm in depth, wherein the slot which houses the energy harvesting material 1418 is about 0.8 mm high in the centre of the sleeve 1412A, 1412B and about 1.5 mm in depth the particular dimensions can be tailored to achieve a desired power out or input force.

The energy harvesting system 1410 operates such that when a force is applied to the energy harvesting material 1418, the energy harvesting material 1418 moves from a pre-deformed first position to a second position, resilient material 1414A, 1414B assists in this movement and the sleeves 1412A, 1412B prevent the energy harvesting material 1418 from damaging or slipping off the resilient material 1414A, 1414B, and wherein when the force is removed from the energy harvesting material 1418, the energy harvesting material 1418 moves to the original pre-deformed first position.

The first part 1416A of the energy generator support 1416 is provided with an aperture 1471 through which the energy harvesting material 1418 can be accessed and actuated. In an alternative not illustrated an external actuator such as a button may be provided which once pressed in turn actuates the energy harvesting material 1418 rather than the energy harvesting material 1418 being actuated by direct contact through the aperture 1471.

The first part 1416A and the second part 1416B of the energy generator support 1416 are provided with interlocking members 1472, 1468 which cooperate to retain the second part 1416B in position with the first part 1416A when assembled. In the embodiment illustrated a retaining clip 1468 is provided on the second part 1416B and a retaining slot 1472 is provided on the first part 1416A.

In the embodiment illustrated a stepped lip 1470 is provided around the edge of the second part 1416B which is configured to enable a watertight seal to be created between the first part 1416A and the second part 1416B when assembled.

The corners 1476 of the first part 1416B are curved to reduce residual stresses at the edge of the energy harvesting system 1410 when assembled and in use.

In the embodiment illustrated as well as of the energy generator support 1416 and 1478 of the second part 1416B acting to form the sleeve clamps they also produce a gap within the energy generator support 1416 to allow the curvature of the deformed energy harvesting material 1418 to fit inside the energy generator support 1416. The portions 1484A, 1484B of the first part 1416A may also act to prevent tampering by providing a one way locking device that is so thin it will snap if opened causing the energy harvesting system 1410 to fail once pressed if the energy harvesting system 1410 has been opened.

The energy harvesting system 1410 is provided with electrode slots 1482 which are used to house connections with external circuitry. The electrode slots 1482 can be used for through hole mounting and surface mounting depending on the application.

The external walls 1492 are in one alternative draft angle walls which allow for injection moulding or casting to increase the ease of manufacture.

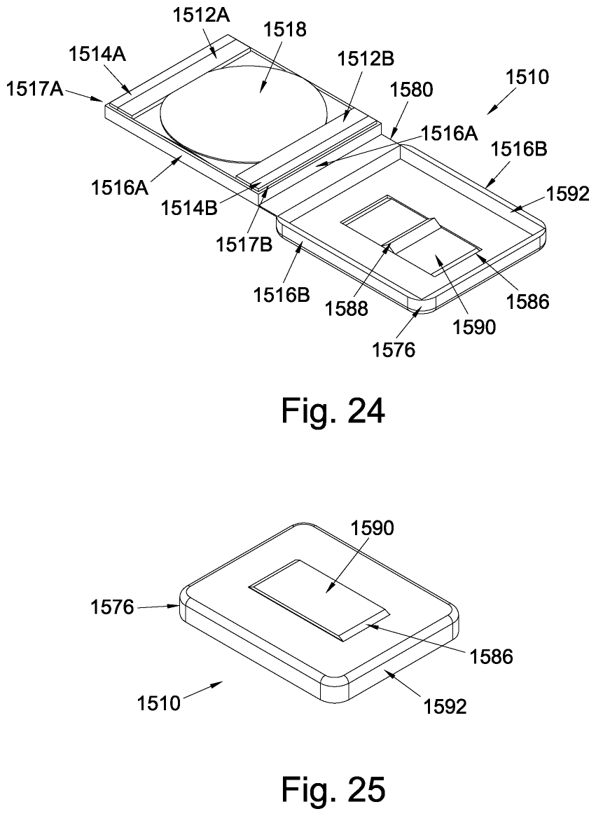

FIGS. 24 to 25 illustrate a seventh embodiment of an energy harvesting system 1510 according to the present invention. The energy harvesting system 1510 has an energy generator support 1516 which is formed in two parts 1516A, 1516B which are connected together. In the embodiment illustrated the two parts 1516A, 1516B are connected together with a living hinge 1580. The two parts 1516A, 1516B of the energy generator support 1516 and living hinge 1580 can be integrally formed through moulding or 3D printing for example. In another alternative the two parts 1516A, 1516B of the energy generator support 1516 may be separate machined components which are connected together on assembly to form the energy generator support 1516.

The first part 1516A of the energy generator support 1516 provides mounting supports 1517A, 1517B between which energy harvesting material 1518 is mounted, and a portion of the second part 1516B of the energy generator support 1516 along with a portion of the first part 1516A of the energy generator support 1516 act together to form a sleeve clamp when the energy harvesting system 1510 is assembled to retain the energy harvesting material 1518 in position as discussed in more detail below.

In the embodiment illustrated the energy harvesting material 1518 is a piezoelectric transducer, in the embodiment illustrated there is a single piezoelectric transducer, in the alternative there may be a plurality of piezoelectric transducers stacked on top of one another.

Where a plurality of piezoelectric transducers are provided which are stacked on top of one another in order for the piezoelectric transducers to operate as a single energy harvesting material they need to be clamped together as illustrated in FIGS. 8 and 9. FIGS. 8 and 9 illustrate the use of 3 piezoelectric transducers 418A, 418B, 418C to form energy harvesting material 418. A clamping band 440 is provided to clamp the piezoelectric transducers 418A, 418B, 418C together to ensure that the electrical signal output from each of the piezoelectric transducers 418A, 418B, 418C is in phase and to improve the consistency and reliability. In the embodiment illustrated the clamping band 440 is an adhesive tape which is wound or wrapped around the piezoelectric transducers 418A, 418B, 418C. In an alternative the clamping band 440 is an adhesive cellulose tape, in a further alternative the clamping band 440 is formed from an injection moulded plastics material.

FIGS. 14 and 15 illustrate the use of 3 piezoelectric transducers 818A, 818B, 818C to form energy harvesting material 818. A clamping band 840 is provided to clamp the piezoelectric transducers 818A, 818B, 818C together to ensure that the electrical signal output from each of the piezoelectric transducers 818A, 818B, 818C is in phase and to improve the consistency and reliability. In the embodiment illustrated the clamping band 840 is an adhesive tape which is wound or wrapped around the piezoelectric transducers 818A, 818B, 818C. In an alternative the clamping band 840 is an adhesive cellulose tape, in a further alternative the clamping band 840 is formed from an injection moulded plastics material. A flexible upper electrode 850A, 850B, 850C and a resilient lower electrode 852A, 852B, 852C are provided for each of the piezoelectric transducers 818A, 818B, 818C wherein each of the piezoelectric transducers 818A, 818B, 818C is arranged between the upper 850A, 850B, 850C and lower electrodes 852A, 852B, 852C. The electrodes 850A, 850B, 850C, 852A, 852B, 852C allow the electrical charge generated to be captured and used to power electrical circuits or in the alternative be stored. In the embodiment illustrated the electrodes 850A, 850B, 850C, 852A, 852B, 852C comprise conductive copper tape which is adhered to the respective upper or lower surface of the piezoelectric material. Each flexible upper electrode 850A, 850B, 850C is provided with a layer of protective insulating material 854A, 854B, 854C, and each resilient lower electrode 852A, 852B, 852C is provided with a layer of protective insulating material 856A, 856B, 856C. The protective insulting material 854A, 854B, 854C, 856A, 856B, 856C ensures that there is no short between the electrodes 850A, 850B, 850C, 852A, 852B, 852C. The layer of protective insulating material 854A, 854B, 854C, 856A, 856B, 856C can simply be a plastic tape.

The mounting supports 1517A, 1517B of the first part 1516A of the energy generator support 1516 each have an internal surface which is provided with a layer of resilient material 1514A, 1514B. In the embodiment illustrated the layer of resilient material 1514A, 1514B, is silicone rubber, in the alternative another hyperelastic material may be used, in another alternative the resilient material could be a spring, such as a leaf spring or a laminated spring. The layer of resilient material 1514A, 1514B is used to reduce the buckling force and allow the energy harvesting material 1518, in this case a piezoelectric transducer, to return to its original position.

The mounting supports 1517A, 1517B of the energy generator support 1516 are each provided with a sleeve 1512A, 1512B and a portion of the second part 1516B of the energy generator support 1516 along with a portion of the first part 1516A of the energy generator support 1516 act together to form sleeve clamps (not illustrated) when the energy harvesting system 1510 is assembled to retain the energy harvesting material 1518 in position. The sleeve 1512A, 1512B is formed from a non-resilient material such as a metallic material such as aluminium or steel or a plastics material such as polylactic acid (PLA) or acrylonitrile butadiene styrene (ABS), preferably where a metallic material is used the metallic material is provided with a coating of a non-conducting material such as a powder coating which also reduces the risk of corrosion of the sleeves 1512A, 1512B. The sleeve 1512A, 1512B is mounted onto the resilient material 1514A, 1514B. The sleeve 1512A, 1512B is then retained in position by sleeve clamp 1524A, 1524B which extends along both sides of the length of the sleeve 1512A, 1512B.

In the embodiment illustrated the sleeve clamp is formed integrally with the energy generator support 1516 by a portion of the second part 1516B of the energy generator support 1516 along with a portion of the first part 1516A of the energy generator support 1516 which act together to form sleeve clamp when the energy harvesting system 1510 is assembled to retain sleeve 1512A, 1512B and the energy harvesting material 1518 in position. The sleeve 1512A, 1512B, is retained in position by the sleeve clamp formed such that the sleeve 1512A, 1512B is able to move backwards and forwards in the same plane as the resilient material 1514A, 1514B, and the energy harvesting material 1518, as energy harvesting material 1518 and the resilient material 1514A, 1514B are deformed, but is not able to move in any other direction.

In the embodiment described sleeves 1512A, 1512B are generally a square C-shape. However, in the alternative the sleeve 1512A, 1512B may be other shapes as illustrated in FIGS. 10 to 12. Whilst these sleeves 512, 612, 712 are also generally C-shaped they have additional features.

Referring to FIG. 10 sleeve 512 is illustrated which is provided with a triangular edge 542 which increases the pressure exerted onto the resilient material. This increased pressure alters the spring stiffness of the resilient material, particularly where the resilient material is a hyperelastic material which results in higher buckling loads of the energy harvesting material with smaller geometric arcs, i.e. smaller deformations, which increases the power output of the energy harvesting material. The use of a staggered wall contact in the form of the triangular edge 542 achieves a higher spring constant. Sleeve 512 is also provided with a square C-shaped slot 544 for ease of locating the energy harvesting material.

Referring to FIG. 11 sleeve 612 is illustrated which is provided with a curved edge 642 which increases the pressure exerted onto the resilient material. This increased pressure alters the spring stiffness of the resilient material, particularly where the resilient material is a hyperelastic material which results in higher buckling loads of the energy harvesting material with smaller geometric arcs, i.e. smaller deformations, which increases the power output of the energy harvesting material. The use of a staggered wall contact in the form of the curved edge 642 achieves a higher spring constant. Sleeve 612 is also provided with a curved C-shaped slot 644 which concentrates the force of the energy harvesting material to the centre of the sleeve 612.

Referring to FIG. 12 sleeve 712 is illustrated which is provided with a staggered triangular edge 742, 746 which increases the pressure exerted onto the resilient material. This increased pressure alters the spring stiffness of the resilient material, particularly where the resilient material is a hyperelastic material which results in higher buckling loads of the energy harvesting material with smaller geometric arcs, i.e. smaller deformations, which increases the power output of the energy harvesting material. The use of a staggered wall contact in the form of the staggered triangular edge 742, 746 achieves a higher spring constant. Sleeve 712 is also provided with a square C-shaped slot 744 for ease of locating the energy harvesting material.

In order to mount the energy harvesting material 1518 within the energy generator support 1516 the layer of resilient material 1514A, 1514B is positioned on mounting supports 1517A, 1517B in the first part 1516A of the energy generator support 1516 then the energy harvesting material 1518 is located sleeves 1512A, 1512B and then placed into position between the layer of resilient material 1514A, 1514B before the second part 1516B of the energy generator support 1516 is put into position to clamp sleeves 1512A, 1512B and retain energy harvesting material 1518 in position. Essentially the two portions 1516A and 1516B of the energy generator support 1516 are formed from a single injection mould that once closed creates the structural support, and environmental protection for the energy harvester 1518. To clamp the energy harvester 1518, it must first be protected by its located sleeves 1512A and 1512B following this a layer of resilient material 1514A, 1514B must be used to against the internal walls of the mounting supports 1517A, 1517B. A press fit ensures ease of fitting for manufacturing purposes and ensures an optimised size.

The length of the sleeves 1512A, 1512B needs to be equal to or greater than the corresponding dimension of the energy harvesting material 1518. The height of the sleeves 1512A, 15128 must be an interference fit into the sleeve clamps formed by the two parts 1516A, 1516B of the energy generator support 1516 and the slot which houses the energy harvesting material 1518 should be an interference fit with the energy harvesting material 1518. In one embodiment the sleeves 1512A, 1512B are grooved with an interference fit, to securely house the energy harvesting material 1518. In one alternative a profile may be used to provide a top clamp for the sleeves to reduce movement and fatigue of the system. The energy harvesting system 1510 can vary in dimensions. In the embodiment illustrated the sleeves 1512A, 1512B are about 3 mm in height, about 26 mm in length and about 3 mm in depth, wherein the slot which houses the energy harvesting material 1518 is about 0.8 mm high in the centre of the sleeve 1512A, 1512B and about 1.5 mm in depth the particular dimensions can be tailored to achieve a desired power out or input force.

The energy harvesting system 1510 operates such that when a force is applied to the energy harvesting material 1518, the energy harvesting material 1518 moves from a pre-deformed first position to a second position, resilient material 1514A, 1514B assists in this movement and the sleeves 1512A, 1512B prevent the energy harvesting material 1518 from damaging or slipping off the resilient material 1514A, 1514B, and wherein when the force is removed from the energy harvesting material 1518, the energy harvesting material 1518 moves to the original pre-deformed first position.

The first part 1516A of the energy generator support 1516 is provided with an external actuator 1590 such as a button which once pressed in turn actuates the energy harvesting material 1518 rather than the energy harvesting material 1518 being actuated directly. In the embodiment illustrated the external actuator 1590 is integrally formed with the first part 1516A of the energy generator support 1516 and is connected to the first part 1516A of the energy generator support 1516 by means of a living hinge 1586. In alternative an aperture may be provided in the first part 1516A of the energy generator support 1516 with a separate external actuator such as a separate button configured to fit within the aperture. The underside of the external actuator 1590 that contacts the energy harvesting material 1518 to actuate the energy harvesting material 1518 is provided with an actuation point 1588 which enables a greater pressure to be applied to the energy harvesting material 1518.

The first part 1516A and the second part 1516B of the energy generator support 1516 may be provided with interlocking members (not shown) which cooperate to retain the second part 1516B in position with the first part 1516A when assembled.

The corners 1576 of the first part 1516B are curved to recued residual stresses at the edge of the energy harvesting system 1510 when assembled and in use.

The energy harvesting system 1510 may be provided with electrode slots (not shown) which can be used to house connections with external circuitry. The electrode slots can also be used for through-hole mounting and surface mounting depending on the application.

The external walls 1592 are in one alternative draft angle walls which allow for injection moulding to increase the ease of manufacture.

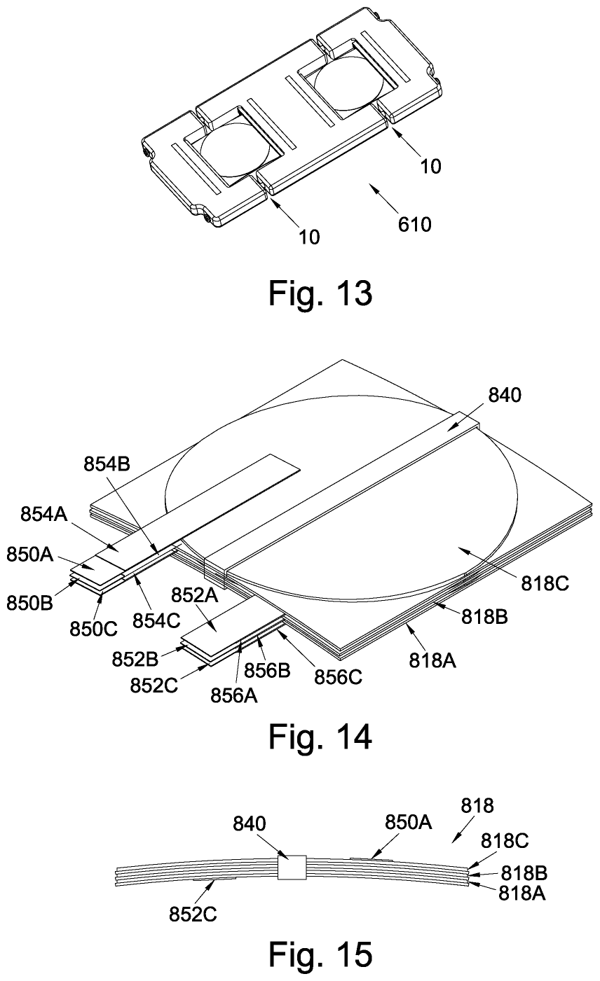

FIG. 13 illustrates an energy harvesting array 610. The energy harvesting array 610 has two energy harvesting systems 10 as illustrated in the first embodiment of the present invention which are connected together. In the alternative there may be more than two energy harvesting systems 10 connected together. Further in the alternative two or more energy harvesting systems 110, 210, 310, 1310, 1410, 1510 may be connected together as described in relation to the second, third, fourth, fifth, sixth or seventh embodiments of the present invention. This modular arrangement can be used to spread an array of energy harvesting systems over a desired area either in a line or in a square or any other desired shape.

1.-19. (canceled)

20. An energy harvesting system comprising:
a) an energy harvesting material which generates energy when deformed or moved from a first position to a second position; and
b) an energy generator support which has first and second mounting supports between which the energy harvesting material is mounted in the first position wherein the first and second mounting supports each have an internal surface and the internal surfaces are each provided with a layer of a resilient material and a layer of a non-resilient material wherein the layer of the non-resilient material engages the energy harvesting material.

21. An energy harvesting system as claimed in claim 20 wherein the resilient material is between the internal surface and the non-resilient material.

22. An energy harvesting system as claimed in claim 20 wherein the non-resilient material provides a barrier between the energy harvesting material and the resilient material.

23. An energy harvesting system as claimed in claim 20 wherein the layer of non-resilient material is a protective sleeve.

24. An energy harvesting system as claimed in claim 20 wherein the resilient material comprises a hyperelastic material.

25. An energy harvesting system as claimed in claim 20 wherein the resilient material comprises silicone.

26. An energy harvesting system as claimed in claim 20 wherein the resilient material comprises a spring.

27. An energy harvesting system as claimed in claim 20 wherein the energy harvesting material comprises an electroactive polymer, an electret and/or a piezoelectric material.

28. An energy harvesting system as claimed in claim 20 wherein the energy harvesting material comprises a planar piezoelectric element.

29. An energy harvesting system as claimed in claim 28 wherein the piezoelectric element comprises a single layer piezoelectric square, circle or rectangle.

30. An energy harvesting system as claimed in claim 28 wherein the piezoelectric element comprises a plurality of piezoelectric elements.

31. An energy harvesting system as claimed in claim 30 wherein when a plurality of piezoelectric elements are provided, the system further comprises a clamp configured to clamp the piezoelectric elements together such that they act as a single piezoelectric element.

32. An energy harvesting system as claimed in claim 31 wherein the clamp comprises a band of cellulose.

33. An energy harvesting system as claimed in claim 31 wherein the clamp comprises an injection moulded plastics band.

34. An energy harvesting system as claimed in claim 20 wherein the energy harvesting material is a flexible energy harvesting material comprising a flexible upper electrode, a layer of piezoelectric material and a resilient lower electrode wherein the layer of piezoelectric material is arranged between the upper and lower electrodes.

35. An energy harvesting system as claimed in claim 20 wherein deformation or movement of the energy harvesting material from the first position to the second comprises physical actuation.

36. An energy harvesting system as claimed in claim 20 wherein the energy generator support comprises two portions which are connected together.

37. An energy harvesting system as claimed in claim 36 wherein the two portions of the energy generator support are connected together with a living hinge.

38. An energy harvesting system as claimed in claim 20 wherein the energy generator support comprises a single portion.

39. A switch comprising an energy harvesting system as claimed in claim 20.
